(19) United States
(12) Patent Application Publication
(10) Pub. No.: US 2022/0246702 A1
(43) Pub. Date: Aug. 4, 2022

(54) DISPLAY DEVICE AND MANUFACTURING METHOD FOR THE SAME

(71) Applicant: Samsung Display Co., LTD., Yongin-si (KR)

(72) Inventors: Byoung Kwon Choo, Hwaseong-si (KR); Seung Bae Kang, Suwon-si (KR); Hee Sung Yang, Hwaseong-si (KR); Bong Gu Kang, Seoul (KR); Tae Wook Kang, Seongnam-si (KR); Woo Jin Cho, Yongin-si (KR)

(21) Appl. No.: 17/511,531

(22) Filed: Oct. 26, 2021

(30) Foreign Application Priority Data
Feb. 2, 2021 (KR) 10-2021-0014999

(51) Int. Cl. H01L 27/32; H01L 51/56

(52) U.S. Cl. CPC H01L 27/3258; H01L 27/3248; H01L 2227/323; H01L 27/3276; H01L 51/56; H01L 27/3265

(57) ABSTRACT

A display device includes: a substrate; a first signal line and a second signal line disposed on the substrate; and an interlayer-insulating layer disposed between the first signal line and the second signal line. The interlayer-insulating layer includes a first portion and a second portion having different heights measured from a surface of the substrate along a first direction that is perpendicular to the surface of the substrate, an upper surface of the first portion of the interlayer-insulating layer is flat, a surface of the second portion of the interlayer-insulating layer is flat, a height of the first portion is lower than a height of the second portion, the interlayer-insulating layer defines a contact hole, and the contact hole is disposed in the first portion of the interlayer-insulating layer.

This application claims priority to Korean Patent Application No. 10-2021-0014999, filed on Feb. 2, 2021, and all the benefits accruing therefrom under 35 U.S.C. § 119, the content of which in its entirety is herein incorporated by reference.

### BACKGROUND

### 1. Field

The present disclosure relates to a display device and a manufacturing method thereof.

### 2. Description of the Related Art

A liquid crystal display (“LCD”), a plasma display panel (“PDP”), an organic light emitting diode device (“OLED” device), a field effect display (“FED”), an electrophoretic display device, or the like are known.

Among them, the organic light emitting diode device has a self-luminance characteristic, and unlike a liquid crystal display device, since it does not require a separate light source, a thickness and weight thereof may be reduced. In addition, the organic light emitting diode device has high-quality characteristics such as low power consumption, high luminance, and high response speed.

### SUMMARY

In the meantime, when a surface of an organic layer of a display device is not flat, a wire formed thereon may be short-circuited due to a step on the surface of the organic layer, and when the organic layer has a too thick thickness, it may be difficult to form contact holes for contact in the organic layer, and accordingly, a failure may occur in connection through the contact holes between layers disposed above and below the organic layer.

Embodiments have been made in effort to provide a display device and a manufacturing method thereof, capable of preventing a short circuit of wires due to a step on an insulating layer of a display device and a connection failure through a contact hole by flattening a surface of the insulating layer, and to easily form a contact hole in the insulating layer.

It is obvious that the aspects of the embodiments are not limited to the above-described aspect, and may be variously extended without departing from the spirit and scope of the embodiments.

An embodiment provides a display device including: a substrate; a first signal line and a second signal line disposed on the substrate; and an interlayer-insulating layer disposed between the first signal line and the second signal line, where the interlayer-insulating layer includes a first portion and a second portion having different heights measured from a surface of the substrate along a first direction that is perpendicular to the surface of the substrate, an upper surface of the first portion of the interlayer-insulating layer is flat, an upper surface of the second portion of the interlayer-insulating layer is flat, a height of the first portion is lower than a height of the second portion, the interlayer-insulating layer defines a contact hole, and the contact hole is disposed in the first portion of the interlayer-insulating layer.

The first portion of the interlayer-insulating layer may overlap the first signal line and the second signal line in a plan view, and the contact hole of the interlayer-insulating layer may expose a portion of the first signal line.

The first portion and the second portion may be polished.

The interlayer-insulating layer may include a first layer and a second layer disposed on the first layer, and a height of a portion of the second layer disposed at the second portion of the interlayer-insulating layer may be the same as a height of a portion of the first layer disposed at the second portion of the interlayer-insulating layer.

The first layer may include a silicon nitride, and the second layer may include a silicon oxide.

The display device may further include a first capacitor electrode and a second capacitor electrode overlapping each other in the plan view with the interlayer-insulating layer therebetween, and the first capacitor electrode and the second capacitor electrode may overlap the first portion of the interlayer-insulating layer in the plan view.

The display device may further include: a first interlayer-insulating layer disposed on the first signal line and the second signal line; and a third signal line disposed on the first interlayer-insulating layer, where the first interlayer-insulating layer may include a third portion and a fourth portion having different heights measured from the surface of the substrate along the first direction, an upper surface of the third portion of the first interlayer-insulating layer may be flat, and an upper surface of the fourth portion of the first interlayer-insulating layer may be flat.

The display device may further include a second interlayer-insulating layer disposed on the third signal line, the second interlayer-insulating layer may include a fifth portion and a sixth portion having different heights measured from the surface of the substrate along the first direction, an upper surface of the fifth portion of the second interlayer-insulating layer may be flat, and an upper surface of the sixth portion of the second interlayer-insulating layer may be flat.

An embodiment provides a manufacturing method of a display device, including: forming a first signal line on a substrate; stacking an insulating layer on the first signal line, where the insulating layer includes a first portion and a second portion having different heights measured from a surface of the substrate along a first direction that is perpendicular to the surface of the substrate; forming an interlayer-insulating layer including a third portion and a fourth portion having different heights measured from the surface of the substrate along the first direction by polishing a surface of the insulating layer; forming a contact hole in the interlayer-insulating layer; and forming a second signal line on the interlayer-insulating layer. An upper surface of the third portion of the interlayer-insulating layer is formed to be flat, and an upper surface of the fourth portion of the interlayer-insulating layer is formed to be flat, the interlayer-insulating layer is formed such that a height of the third portion is lower than a height of the fourth portion, and the contact hole of the interlayer-insulating layer is disposed in the third portion of the interlayer-insulating layer.

A first surface step difference between the first portion and the second portion of the insulating layer may be greater than a second surface step difference between the third portion and the fourth portion of the interlayer-insulating layer.

The forming of the contact hole may include forming the contact hole of the interlayer-insulating layer to overlap the first signal line.

The forming of the interlayer-insulating layer may include polishing first portion and the second portion using a planarization device.

The stacking of the insulating layer may include stacking a first layer and stacking a second layer on the first layer, and the polishing of the surface of the insulating layer may include polishing the second layer by using the first layer as a stopper.

The first layer may include a silicon nitride, and the second layer may include a silicon oxide.

The manufacturing method may further include: forming a first capacitor electrode and a second capacitor electrode overlapping each other with the interlayer-insulating layer therebetween in a plan view, and the first capacitor electrode and the second capacitor electrode may overlap the third portion of the interlayer-insulating layer in the plan view.

The manufacturing method may further include: forming a first interlayer-insulating layer disposed on the first signal line and the second signal line; and forming a third signal line on the first interlayer-insulating layer. The forming of the first interlayer-insulating layer may include: stacking a first insulating layer on the first signal line and the second signal line, where the first insulating layer includes a fifth portion and a sixth portion having different heights measured from the surface of the substrate along the first direction; and forming the first interlayer-insulating layer including a seventh portion and an eighth portion having different heights measured from the surface of the substrate along the first direction by polishing the first insulating layer, and an upper surface of the seventh portion of the first interlayer-insulating layer may be formed to be flat, and an upper surface of the eighth portion of the first interlayer-insulating layer may be formed to be flat.

The manufacturing method may further include forming a second interlayer-insulating layer on the third signal line. The forming of the second interlayer-insulating layer may include: stacking a second insulating layer on the third signal line, where the second insulating layer includes a ninth portion and a tenth portion having different heights measured from the surface of the substrate along the first direction; and forming the second interlayer-insulating layer including an eleventh portion and a twelfth portion having different heights measured from the surface of the substrate along the first direction by polishing the second insulating layer, and an upper surface of the eleventh portion of the second interlayer-insulating layer may be formed to be flat, and an upper surface of the twelfth portion of the second interlayer-insulating layer may be formed to be flat.

In accordance with the display device and the manufacturing method thereof according to the embodiments, it is possible to prevent a short circuit of wires due to a step on an insulating layer of a display device and a connection failure through a contact hole by flattening a surface of the insulating layer, and to easily form a contact hole in the insulating layer.

It is obvious that the effects of the embodiments are not limited to the above-described effect, and may be variously extended without departing from the spirit and scope of the embodiments.

### BRIEF DESCRIPTION OF THE DRAWINGS

FIG. 1 illustrates a circuit diagram of one pixel of a display device according to an embodiment.

FIG. 2 illustrates a cross-sectional view showing a portion of one pixel of a display device according to an embodiment.

FIG. 3A to FIG. 3D illustrate cross-sectional views showing a manufacturing method of a display device according to an embodiment.

FIG. 4 illustrates a cross-sectional view of a display device according to another embodiment.

FIG. 5A and FIG. 5B illustrate cross-sectional views showing a manufacturing method of a display device according to another embodiment.

FIG. 6 illustrates a circuit diagram of one pixel of a display device according to another embodiment.

FIG. 7 illustrates a cross-sectional view showing a portion of one pixel of a display device according to still another embodiment.

FIG. 8A to FIG. 8K illustrate cross-sectional views showing a manufacturing method of a display device according to still another embodiment.

FIG. 9 illustrates a circuit diagram of one pixel of a display device according to another embodiment.

FIG. 10 illustrates a layout view of one pixel of a display device according to an embodiment.

FIG. 11 illustrates a cross-sectional view taken along line XI-XI′ of FIG. 10.

FIG. 12A to FIG. 12M illustrate top plan views showing a manufacturing method of a display device according to another embodiment.

FIG. 13A to FIG. 13G illustrate cross-sectional views showing a manufacturing method of a display device according to another embodiment.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of the embodiments.

To clearly describe the embodiments, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the embodiments are not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/ or.” As used herein, the term “and/or” includes any and all combinations of one or more of the associated listed items.

In addition, unless explicitly described to the contrary, the word “comprise” and variations such as “comprises” or “comprising” will be understood to imply the inclusion of stated elements but not the exclusion of any other elements.

Further, in the specification, the phrase “in a plan view” means when an object portion is viewed from above (i.e., viewed in a first direction Dz), and the phrase “in a cross-sectional view” means when a cross-section taken by vertically cutting an object portion is viewed from the side.

In addition, in the specification, “connected” means that two or more components are not only directly connected, but two or more components are connected indirectly through other components, physically connected as well as being electrically connected, or it may have been referred to as different names depending on the location or function, but may mean integral.

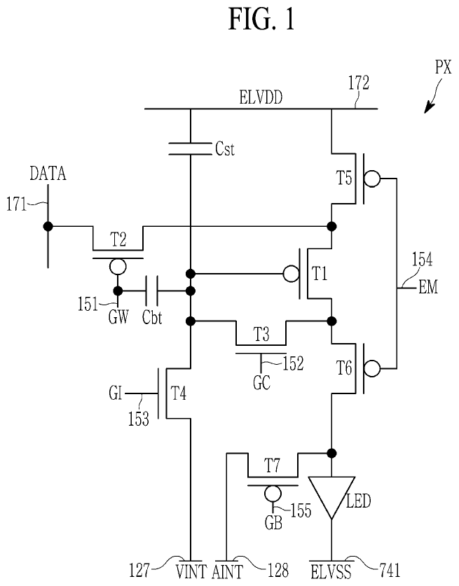

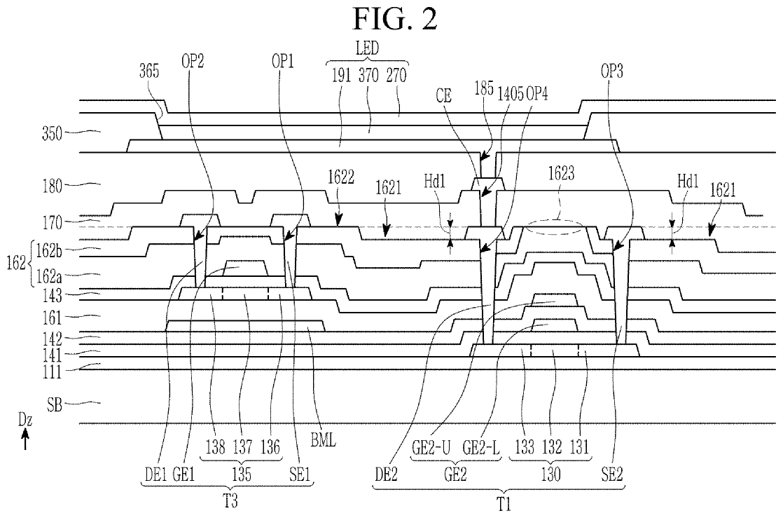

A display device according to an embodiment will now described with FIG. 1 and FIG. 2. FIG. 1 illustrates a circuit diagram of one pixel of a display device according to an embodiment, and FIG. 2 illustrates a cross-sectional view showing a portion of one pixel of a display device according to an embodiment.

As illustrated in FIG. 1, according to the present embodiment, one pixel of the display device includes a plurality of transistors T1, T2, T3, T4, T5, T6, and T7, a storage capacitor Cst, a boost capacitor Cbt, and a light emitting diode LED connected to various wires 127, 128, 151, 152, 153, 154, 155, 171, 172, and 741.

The wires 127, 128, 151, 152, 153, 154, 155, 171, 172, and 741 are connected to one pixel PX. The wires include a first initialization voltage line 127, a second initialization voltage line 128, a first scan line 151, a second scan line 152, an initialization control line 153, an emission control line 154, a bypass control line 155, a data line 171, a driving voltage line 172, and a common voltage line 741.

The first scan line 151 is connected to a gate driver (not illustrated) to transmit a first scan signal GW to the second transistor T2. A voltage having a polarity that is opposite to a polarity of the voltage applied to the first scan line 151 may be applied to the second scan line 152 at the same timing as a signal of the first scan line 151. For example, when a negative voltage is applied to the first scan line 151, a positive voltage may be applied to the second scan line 152. The second scan line 152 transmits a second scan signal GC to the third transistor T3.

The initialization control line 153 transmits an initialization control signal GI to the fourth transistor T4. The bypass control line 155 transfers a bypass signal GB to the seventh transistor T7. The bypass control line 155 may be formed by a previous-stage first scan line 151. The emission control line 154 transmits an emission control signal EM to the fifth transistor T5 and the sixth transistor T6.

The data line 171 is a wire for transmitting a data voltage DATA generated by a data driver (not illustrated), and luminance of the organic light emitting diode LED that emits light is changed depending on the data voltage DATA applied to the pixel PX.

The driving voltage line 172 applies a driving voltage ELVDD. The first initialization voltage line 127 transfers a first initialization voltage VINT, and the second initialization voltage line 128 transfers the second initialization voltage AINT. The common voltage line 741 applies a common voltage ELVSS to a cathode of the light emitting diode LED. In the present embodiment, voltages applied to the driving voltage line 172, the first and second initialization voltage lines 127 and 128, and the common voltage line 741 may be constant voltages, respectively.

The transistors may include a driving transistor T1, a second transistor T2, a third transistor T3, a fourth transistor T4, a fifth transistor T5, a sixth transistor T6, and a seventh transistor T7. The transistors may include an oxide transistor including an oxide semiconductor and a polycrystalline transistor including a polycrystalline semiconductor. For example, the third transistor T3 and the fourth transistor T4 may be formed as oxide transistors, and the driving transistor T1, the second transistor T2, the fifth transistor T5, the sixth transistor T6, and the seventh transistor T7 may be formed as silicon transistors. However, the embodiment according to the invention is not limited thereto, and the transistors may all be made as silicon transistors in another embodiment.

Previously, a case has been described that one pixel PX includes seven transistors T1 to T7, one storage capacitor Cst, and one boost capacitor Cbt, but the embodiment according to the invention is not limited thereto, and the number of transistors, the number of capacitors, and their connection relationship may be variously changed.

According to the embodiment shown in FIG. 2, for convenience of description, the first transistor T1, the third transistor T3, and the light emitting diode LED are mainly illustrated, but the embodiment is not limited thereto, and as previously described with reference to FIG. 1, other transistors may be included in addition to the first transistor T1 and the third transistor T3.

Referring to FIG. 2, a buffer layer 111 may be disposed on a substrate SB.

The substrate SB may include a polymer such as polyimide or polyamide, or an insulating material such as glass, and may be optically transparent.

The substrate SB may include a first transparent layer (not illustrated) and a second transparent layer (not illustrated) overlapping each other in a plan view, and a first barrier layer (not illustrated) disposed between the first transparent layer and the second transparent layer.

Each of the first transparent layer and the second transparent layer may include a polymer such as polyimide or polyamide. Each of the first transparent layer and the second transparent layer may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

A barrier layer may prevent penetration of moisture, etc., and may include, e.g., an inorganic insulating material such as a silicon oxide (SiOₓ), a silicon nitride (SiNₓ), and a silicon oxynitride (SiOₓN_{y}). The barrier layer may include amorphous silicon (Si).

The buffer layer 111 is disposed between the substrate SB and the second semiconductor 130 to block impurities from the substrate SB during a crystallization process for forming polycrystalline silicon, thereby improving a characteristic of the polycrystalline silicon.

The buffer layer 111 may include an inorganic insulating material such as a silicon oxide (SiOₓ), a silicon nitride (SiNₓ), and a silicon oxynitride (SiOₓN_{y}). The buffer layer 111 may include amorphous silicon (Si).

A second semiconductor 130 of the first transistor T1 may be disposed on the buffer layer 111. The second semiconductor 130 may include a polycrystalline silicon material. That is, the second semiconductor 130 may be formed as a polycrystalline semiconductor. The second semiconductor 130 may include a source region 131, a channel region 132, and a drain region 133.

The source region 131 of the second semiconductor 130 may be connected to a second source electrode SE2, and the drain region 133 of the second semiconductor 130 may be connected to a second drain electrode DE2.

A first gate insulating layer 141 may be disposed on the second semiconductor 130

The first gate insulating layer 141 may have a single or multi-layered structure including a silicon nitride, a silicon oxide, a silicon oxynitride, or the like.

A second gate lower electrode GE2-L may be disposed on the first gate insulating layer 141. The second gate lower electrode GE2-L may include molybdenum (Mo), aluminum (Al), copper (Cu), and/ or titanium (Ti), and may have a single or multi-layered structure having the same.

A second gate insulating layer 142 may be disposed on the second gate lower electrode GE2-L. The second gate insulating layer 142 may include a silicon nitride, a silicon oxide, a silicon oxynitride, or the like. The second gate insulating layer 142 may have a single or multi-layered structure including a silicon nitride, a silicon oxide, a silicon oxynitride, or the like.

A second gate upper electrode GE2-U may be disposed on the second gate insulating layer 142. The second gate lower electrode GE2-L and the second gate upper electrode GE2-U may overlap each other in a plan view with the second gate insulating layer 142 therebetween. The second gate upper electrode GE2-U and the second gate lower electrode GE2-L constitute a second gate electrode GE2. The second gate electrode GE2 may overlap the channel region 132 of the second semiconductor 130 in a direction that is perpendicular to the substrate SB.

A metal layer BML located at the same layer as the second gate upper electrode GE2-U may be disposed on the second gate insulating layer 142, and may overlap the third transistor T3 to be described later. The metal layer BML may be connected to a driving voltage line or a gate electrode or a source electrode of the third transistor T3 to serve as a lower gate electrode.

Each of the second gate upper electrode GE2-U and the metal layer BML may include molybdenum (Mo), aluminum (Al), copper (Cu), silver (Ag), chromium (Cr), tantalum (Ta), titanium (Ti), etc., and may have a single or multi-layered structure including the same.

The second semiconductor 130, the second gate electrode GE2, the second source electrode SE2, and the second drain electrode DE2 constitute the first transistor T1. The first transistor T1 may be a driving transistor connected to the light emitting diode LED, and may be formed as a transistor including a polycrystalline semiconductor.

A first interlayer-insulating layer 161 may be disposed on the second gate electrode GE2. The first interlayer-insulating layer 161 may include a silicon nitride, a silicon oxide, a silicon oxynitride, or the like. The first interlayer-insulating layer 161 may be formed as a multilayer including a silicon nitride and a silicon oxide. In this case, in the first interlayer-insulating layer 161, the layer including the silicon nitride may be disposed closer to the substrate SB than the layer including the silicon oxide.

A first semiconductor 135 of the third transistor T3 may be disposed on the first interlayer-insulating layer 161. The first semiconductor 135 may overlap the metal layer BML in a plan view.

The first semiconductor 135 may include an oxide semiconductor. The oxide semiconductor may include at least one of indium (In) oxide, tin (Sn) oxide, zinc (Zn) oxide, hafnium (Hf) oxide, and aluminum (Al) oxide. For example, the first semiconductor 135 may include an indium-gallium-zinc oxide (“IGZO”).

The first semiconductor 135 includes a channel region 137, and a source region 136 and a drain region 138 disposed at opposite sides of the channel region 137. The source region 136 of the first semiconductor 135 may be connected to a first source electrode SEL and the drain region 138 of the first semiconductor 135 may be connected to a first drain electrode DE1.

A third gate insulating layer 143 may be disposed on the first semiconductor 135. The third gate insulating layer 143 may include a silicon nitride, a silicon oxide, a silicon oxynitride, or the like.

In the illustrated embodiment, the third gate insulating layer 143 may be disposed on entire surfaces of the first semiconductor 135 and the first interlayer-insulating layer 161 exposed. Accordingly, the third gate insulating layer 143 covers upper and side surfaces of the source region 136, the channel region 137, and the drain region 138 of the first semiconductor 135.

When the third gate insulating layer 143 does not cover the upper surfaces of the source region 136 and the drain region 138, some materials of the first semiconductor 135 may move to the side of the third gate insulating layer 143. In the present embodiment, since the third gate insulating layer 143 is disposed on the entire surfaces of the first semiconductor 135 and the first interlayer-insulating layer 161, it is possible to prevent a short circuit between the first semiconductor 135 and the first gate electrode GE1 clue to diffusion of metal particles.

However, embodiments according to the invention are not limited thereto, and the third gate insulating layer 143 may not be disposed on the entire surfaces of the first semiconductor 135 and the first interlayer-insulating layer 161 in another embodiment. For example, the third gate insulating layer 143 may be disposed only between the first gate electrode GE1 and the first semiconductor 135. That is, the third gate insulating layer 143 may overlap the channel region 137 of the first semiconductor 135, and may not overlap the source region 136 and/or the drain region 138 in a plan view. Accordingly, a length of the channel of the semiconductor may be shortened in a process of implementing high resolution.

A first gate electrode GE1 may be disposed on the third gate insulating layer 143.

The first gate electrode GE1 may overlap the channel region 137 of the first semiconductor 135 in a direction that is perpendicular to the substrate SB (i.e., in a plan view). The first gate electrode GE1 may include molybdenum (Mo), aluminum (Al), copper (Cu), and/ or titanium (Ti), and may have a single or multi-layered structure having the same. For example, the first gate electrode GE1 may include a lower layer containing titanium and an upper layer containing molybdenum, and the lower layer containing titanium may prevent diffusion of fluorine (F), which is an etching gas, during dry etching of the upper layer.

The first semiconductor 135, the first gate electrode GEL the first source electrode SEL and the first drain electrode DE1 may constitute the third transistor T3. The third transistor T3 may be formed as a transistor including an oxide semiconductor.

A second interlayer-insulating layer 162 may be disposed on the first gate electrode GE1. The second interlayer-insulating layer 162 may include a first layer 162a and a second layer 162b disposed on the first layer 162a.

The first layer 162a of the second interlayer-insulating layer 162 may include an insulating material, and for example, the first layer 162a of the second interlayer-insulating layer 162 may include a silicon nitride.

The second layer 162b of the second interlayer-insulating layer 162 may include an insulating material, and for example, the second layer 162b of the second interlayer-insulating layer 162 may include a silicon oxide.

The second interlayer-insulating layer 162 may include a first portion 1621 and a second portion 1622 having different heights measured from a surface of the substrate along a first direction Dz that is perpendicular to the major surface of the substrate SB, and for example, the first portion 1621 of the second interlayer-insulating layer 162 may be a portion having a relatively low height measured from the surface of the substrate SB along the first direction Dz, and the second portion 1622 of the second interlayer-insulating layer 162 may be a portion having a relatively high height measured from the surface of the substrate SB along the first direction Dz.

The first portion 1621 and the second portion 1622 of the second interlayer-insulating layer 162 may have a height difference, i.e., a first step Hd1 in the first direction Dz.

An upper surface of the first portion 1621 of the second interlayer-insulating layer 162 may be flat, and an upper surface of the second portion 1622 of the second interlayer-insulating layer 162 may also be flat.

As indicated by a dotted ellipse 1623, a height of a portion of the second layer 162b of the second interlayer-insulating layer 162, measured from the surface of the substrate SB along the first direction Dz, may be substantially the same as a height of the first layer 162a of the second interlayer-insulating film 162 at the dotted ellipse 1623 (i.e., a portion of the second portion 1622), measured from the surface of the substrate SB along the first direction Dz.

In the second interlayer-insulating layer 162 and the third gate insulating layer 143, a first contact hole OP1 and a second contact hole OP2 overlapping the source region 136 and the drain region 138 of the first semiconductor 135, respectively, are defined.

In addition, a third contact hole OP3 and a fourth contact hole OP4 overlapping the source region 131 and the drain region 133 of the second semiconductor 130, respectively, are defined in the second interlayer-insulating layer 162, the third gate insulating layer 143, the first interlayer-insulating layer 161, the second gate insulating layer 142, and the first gate insulating layer 141.

The third contact hole OP3 and the fourth contact hole OP4 overlapping the source region 131 and the drain region 133 of the second semiconductor 130, respectively, are defined in a relatively large number of insulating layers 141 and 142, 161, 143, and 162, and thus a cross-sectional area of the third contact hole OP3 and the fourth contact hole OP4 may be widened, and the third contact hole OP3 and the fourth contact hole OP4 may not be formed in some insulating layers without defects.

However, in accordance with the display device according to the present embodiment, the third contact hole OP3 and the fourth contact hole OP4 defined in the relatively large number of insulating layers 141, 142, 161, 143, and 162 are disposed in the first portion 1621 of the second interlayer-insulating layer 162, having the relatively low height measured from the surface of the substrate along the first direction Dz.

Accordingly, thicknesses of the insulating layers 141, 142, 161, 143, and 162 in which the third contact hole OP3 and the fourth contact hole OP4 are defined may be reduced, and thus, the third contact hole OP3 and the fourth contact hole OP4 may be formed without defects even while planar areas (i.e., area in a plan view) of the third contact hole OP3 and the fourth contact hole OP4 formed in the relatively large number of insulating layers 141, 142, 161, 143, and 162 are not widened.

A first source electrode SE1, a first drain electrode DE1, a second source electrode SE2, and a second drain electrode DE2, may be disposed on the second interlayer-insulating layer 162.

The first source electrode SE1, the first drain electrode DE1, the second source electrode SE2, and the second drain electrode DE2 may include, e.g., aluminum (Al), molybdenum (Mo), titanium (Ti), tungsten (W), and/or copper (Cu), and may have a single or multi-layered structure having the same. For example, the first source electrode SE1, the first drain electrode DE1, the second source electrode SE2, and the second drain electrode DE2 may have a triple layer structure including a lower layer including a refractory metal such as titanium, molybdenum, chromium, and tantalum, or an alloy thereof, an interlayer layer including an aluminum-based metal, a silver-based metal, and a copper-based metal with low resistivity, and an upper layer including a refractory metal such as titanium, molybdenum, chromium, or tantalum.

The first source electrode SE1 may be connected to the source region 136 of the first semiconductor 135 through the first contact hole OP1, and the first drain electrode DE1 may be connected to the drain region 138 of the first semiconductor 135 through the second contact hole OP2.

The second source electrode SE2 may be connected to the source region 131 of the second semiconductor 130 through the third contact hole OP3, and the second drain electrode DE2 may be connected to the drain region 133 of the second semiconductor 130 through the fourth contact hole OP4.

As described above, since the first portion 1621 and the second portion 1622 of the second interlayer-insulating layer 162 each have a flat surface, the second source electrode SE2 and the second drain electrode DE2 and the first source electrode SE1 and the first drain electrode DE1 formed thereon may be disposed on the flat surface, thereby effectively preventing disconnection of the second source electrode SE2 and the second drain electrode DE2, the first source electrode SE1, and the first drain electrode DE1.

A first insulating layer 170 may be disposed on the first source electrode SE1, the first drain electrode DE1, the second source electrode SE2, and the second drain electrode DE2. The first insulating layer 170 may be an organic layer or an inorganic layer. For example, the first insulating layer 170 may include a general purpose polymer such as poly(methyl methacrylate) (“PMMA”) or polystyrene (“PS”), a polymer derivative having a phenolic group, an organic insulating material such as an acrylic polymer, an imide polymer, a polyimide, an acrylic polymer, a siloxane polymer, etc. A connection electrode CE, a data line 171, and a driving voltage line 172 may be disposed on the first insulating layer 170. The connection electrode CE and the data line 171 may include, e.g., aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and may have a single or multi-layered structure including the same.

The connection electrode CE is connected to the second drain electrode DE2 through a contact hole 165 defined in the first insulating layer 170.

A second insulating layer 180 may be disposed on the first insulating layer 170, the connection electrode CE, and the data line 171. The second insulating layer 180 may serve to eliminate and planarize a step in order to increase emission efficiency of a light emission layer to be formed thereon. The second insulating layer 180 may include a general purpose polymer such as poly(methyl methacrylate) (PMMA) or polystyrene (PS), a polymer derivative having a phenolic group, an organic insulating material such as an acrylic polymer, an imide polymer, a polyimide, an acrylic polymer, a siloxane polymer, etc.

A pixel electrode 191 may be disposed on the second insulating layer 180. The pixel electrode 191 may be connected to the second drain electrode DE2 through a contact hole 185 of the second insulating layer 180.

The pixel electrode 191 may be individually disposed for each pixel PX. The pixel electrode 191 may include a metal such as silver (Ag), lithium (Li), calcium (Ca), aluminum (Al), magnesium (Mg), and gold (Au), and may also include a transparent conductive oxide (“TCO”) such as indium zinc oxide (“IZO”) and indium tin oxide (“ITO”). The pixel electrode 191 may be a single layer including a metal material or a transparent conductive oxide, or a multiple layer including the same. For example, the pixel electrode 191 may have a triple layer structure of indium tin oxide (ITO)/silver (Ag)/ indium tin oxide (ITO).

A pixel defining layer 350 may be disposed on the pixel electrode 191. The pixel defining layer 350 may include a general purpose polymer such as poly(methyl methacrylate) (PMMA) or polystyrene (PS), a polymer derivative having a phenolic group, an organic insulating material such as an acrylic polymer, an imide polymer, a polyimide, an acrylic polymer, a siloxane polymer, etc. The pixel defining layer 350 may include a black dye, and may not transmit light.

A pixel opening 365 may be formed in the pixel defining layer 350, and the pixel opening 365 of the pixel defining layer 350 may overlap the pixel electrode 191. An emission layer 370 may be disposed in the pixel opening 365 of the pixel defining layer 350.

The emission layer 370 may include a material layer that uniquely emits light of primary colors such as red, green, and blue. The emission layer 370 may have a structure in which a plurality of material layers emitting light of different colors are stacked.

For example, the emission layer 370 may be an organic emission layer, and the organic emission layer may include a plurality of layers including at least one of an emission layer, a hole-injection layer (“HIL”), a hole-transporting layer (“HTL”), an electron-transporting layer (“ETL”), and an electron-injection layer (“EIL”). When the organic emission layer includes all of them, the hole-injection layer may be disposed on the pixel electrode 191 which is an anode, and the hole-transporting layer, the emission layer, the electron-transporting layer, and the electron-injection layer may be sequentially stacked thereon.

A common electrode 270 may be disposed on the emission layer 370 and the pixel defining layer 350. The common electrode 270 may be disposed in common in all the pixels PX, and may receive a common voltage ELVSS through a common voltage transfer unit (not illustrated) of the non-display area PA.

The common electrode 270 may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), etc., or a transparent conductive oxide (TCO) such as indium tin oxide (ITO) or indium zinc oxide (IZO).

The pixel electrode 191, the emission layer 370, and the common electrode 270 may constitute a light emitting diode LED. Herein, the pixel electrode 191 may be an anode which is a hole-injection electrode, and the common electrode 270 may be a cathode which is an electron-injection electrode. However, the embodiment according to the invention is not limited thereto, and the pixel electrode 191 may be a cathode and the common electrode 270 may be an anode depending on a driving method of an organic light emitting diode device.

When holes and electrons are injected from the pixel electrode 191 and the common electrode 270 into the emission layer 370, excitons formed by combining the injected holes and electrons are emitted when they fall from an excited state to a ground state.

The third transistor T3, which is a part of a switching transistor of the display device according to an embodiment, may include an oxide semiconductor, and the first transistor T1, which is a driving transistor, may include a polycrystalline semiconductor. For high-speed driving, a video may be more naturally expressed by raising the frequency of about 60 Hz to about 120 Hz, but this increases power consumption. A frequency when driving a still image may be reduced in order to compensate for the increased power consumption. For example, when the still image is driven, it may be driven at about 1 Hz. When the frequency is reduced in this way, a leakage current may occur. In the display device according to an embodiment, the first transistor T1, which is a switching transistor, may include an oxide semiconductor, thereby minimizing the leakage current. In addition, the first transistor T1, which is a driving transistor, may include a polycrystalline semiconductor, thereby having a high degree of electron mobility. That is, the switching transistor and the driving transistor may include different semiconductor materials, thereby driving more stably and having high reliability.

Although not illustrated, an encapsulation layer (not illustrated) may be disposed on the common electrode 270, and the encapsulation layer may cover not only an upper surface but also a side surface of the pixel to encapsulate a pixel portion. The encapsulation layer may include a plurality of layers, and may be a composite layer including both an inorganic layer and an organic layer.

As such, in accordance with the display device according to an embodiment, a surface of the second interlayer-insulating layer 162, which is an insulating layer in which a contact hole is defined, has a first portion 1621 and a second portion 1622 having a first step Hd1, and each upper surface of the first portion 1621 and the second portion 1622 may be planar. Accordingly, contact holes may be formed without defects in a plurality of insulating layers without increasing planar areas thereof, and disconnection of electrodes disposed on the second interlayer-insulating layer 162 may be effectively prevented.

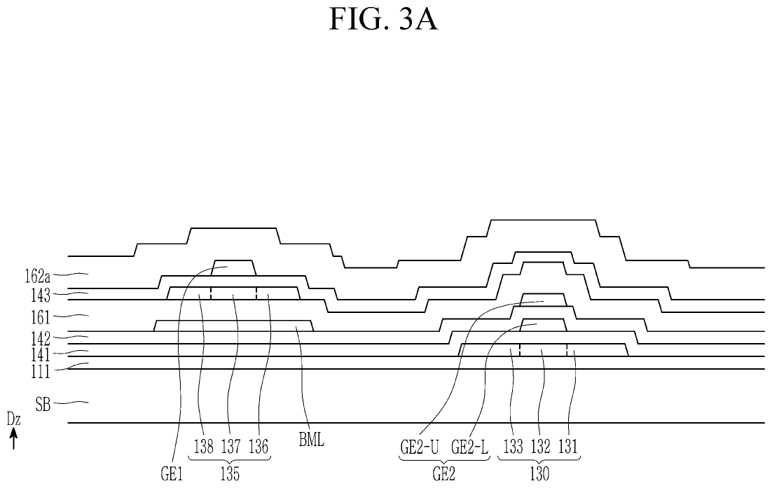

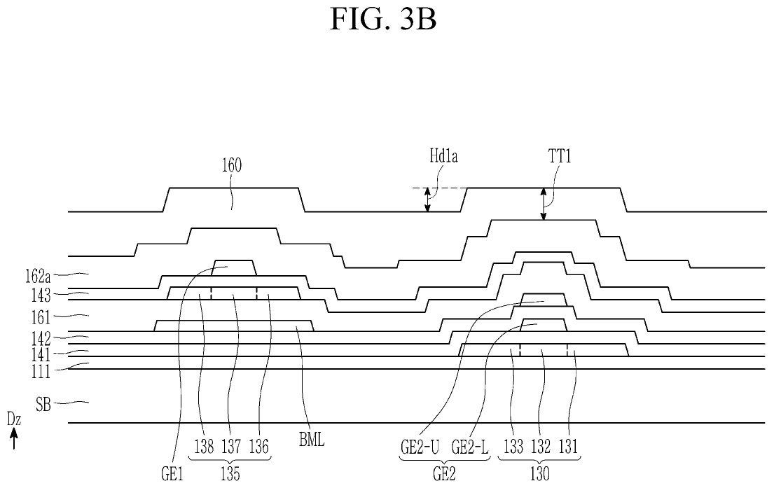

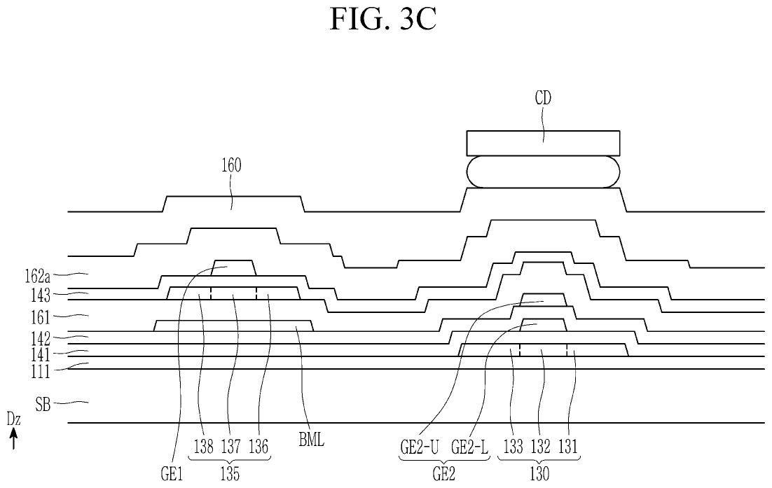

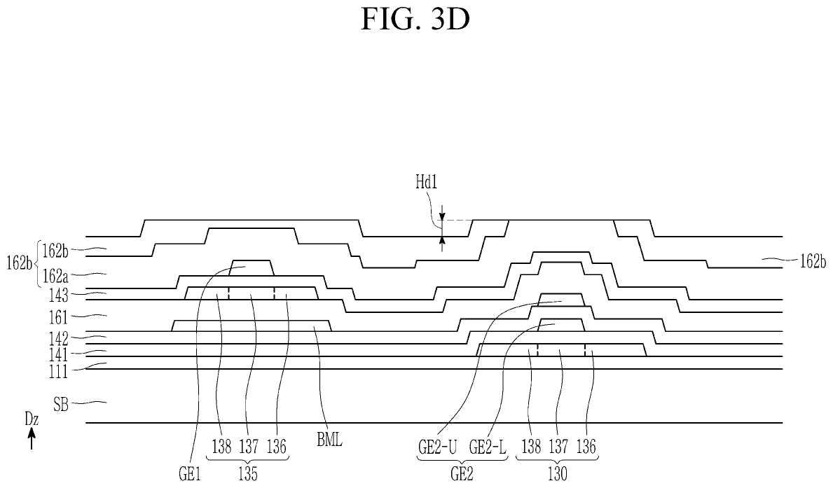

Hereinafter, a manufacturing method of a display device according to an embodiment will be described with reference to FIG. 3A to FIG. 3D together with FIG. 2. FIG. 3A to FIG. 3D illustrate cross-sectional views showing a manufacturing method of a display device according to an embodiment.

As illustrated in FIG. 3A, the buffer layer 111 is deposited on the substrate SB, and the second semiconductor 130 is formed on the buffer layer 111, the first gate insulating layer 141 is deposited on the second semiconductor 130, the second gate lower electrode GE2-L is formed on the first gate insulating layer 141, the second gate insulating layer 142 is deposited on the second gate lower electrode GE2-L, the second gate upper electrode GE2-U and the metal layer BML are formed on the second gate insulating layer 142, the first interlayer-insulating layer 161 is deposited on the second gate upper electrode GE2-U and the metal layer BML, the first semiconductor 135 is formed on the first interlayer-insulating layer 161, and the third gate insulating layer 143 is deposited on the first semiconductor 135, the first gate electrode GE1 is formed on the third gate insulating layer 143, and the first layer 162a of the second interlayer-insulating layer 162 is formed on the first gate electrode GE1.

As illustrated in FIG. 3B, an insulating layer 160 constituting the second layer 162b of the second interlayer-insulating layer 162 is deposited on the first layer 162a of the second interlayer-insulating layer 162. In this case, a surface of the insulating layer 160 may have a step Hd1a depending on a position thereof, and the step Hd1a of the insulating layer 160 may be larger than the first step Hd1 of the surface of the second interlayer-insulating layer 162 described above. A thickness TT1 of the insulating layer 160 may not be thick such that the surface thereof is flat.

Referring to FIG. 3C, the surface of the insulating layer 160 is polished by using a planarization device CD. In this case, the first layer 162a of the second interlayer-insulating layer 162 may serve as a stopper for a polishing process, and the insulating layer 160 may be polished until an upper surface of the insulating layer 160 and the first layer 162a of the second interlayer-insulating layer 162 have the same height. The first layer 162a of the second interlayer-insulating layer 162 may include a silicon nitride, and the insulating layer 160 may include a silicon oxide.

A second layer 162b of the second interlayer-insulating layer 162 may have the first step Hd1 in a height difference between the first portion 1621 and the second portion 1622.

Specifically, the second interlayer-insulating layer 162 may include a first portion 1621 and a second portion 1622 having different heights measured from a surface of the substrate along the first direction Dz, and for example, the first portion 1621 of the second interlayer-insulating layer 162 may be a portion having a relatively low height, and the second portion 1622 of the second interlayer-insulating layer 162 may be a portion having a relatively high height.

The first portion 1621 and the second portion 1622 of the second interlayer-insulating layer 162 may have a height difference, i.e., a first step Hd1.

An upper surface of the first portion 1621 of the second interlayer-insulating layer 162 may be flat, and an upper surface of the second portion 1622 of the second interlayer-insulating layer 162 may also be flat.

A height of a portion of the second portion 1622 of the second interlayer-insulating layer 162 may be substantially the same as a height of the first layer 162a of the second interlayer-insulating layer 162.

Subsequently, the first contact hole OP1 and the second contact hole OP2 are formed in the second interlayer-insulating layer 162 and the third gate insulating layer 143, and the third contact hole OP3 and a fourth contact hole OP4 are formed in the second interlayer-insulating layer 162, the third gate insulating layer 143, the first interlayer-insulating layer 161, the second gate insulating layer 142, and the first gate insulating layer 141. In this case, the third contact hole OP3 and the fourth contact hole OP4 defined in the relatively large number of insulating layers 141, 142, 161, 143, and 162 are formed in the first portion 1621 of the second interlayer-insulating layer 162, having the relatively low height measured from the surface of the substrate along the first direction Dz.

Accordingly, the third contact hole OP3 and the fourth contact hole OP4 may be formed without defects even while planar areas of the third contact hole OP3 and the fourth contact hole OP4 formed in the relatively large number of insulating layers 141, 142, 161, 143, and 162 are not widened.

Next, a first source electrode SE1 and a first drain electrode DE1, and a second source electrode SE2 and a second drain electrode DE2, may be formed on the second interlayer-insulating layer 162. Since the first portion 1621 and the second portion 1622 of the second interlayer-insulating layer 162 each have a flat surface, the second source electrode SE2 and the second drain electrode DE2 and the first source electrode SE1 and the first drain electrode DE1 formed thereon may be disposed on the flat surface, thereby effectively preventing disconnection of the second source electrode SE2 and the second drain electrode DE2, the first source electrode SE1, and the first drain electrode DE1.

Next, the first insulating layer 170 is formed on the first source electrode SE1, the first drain electrode DE1, the second source electrode SE2, and the second drain electrode DE2, the connection electrode CE, the data line 171, and the driving voltage line 172 are formed on the first insulating layer 170, and second insulating layer 180 is formed on the connection electrode CE and the data line 171, the pixel electrode 191 is formed on the second insulating layer 180, the pixel defining layer 350 is formed on the pixel electrode 191, and the light emission layer 370 is formed in the pixel opening 365 of the pixel defining layer 350, and the common electrode 270 is formed on the emission layer 370 and the pixel defining layer 350 to form the display device illustrated in FIG. 2.

In accordance with the manufacturing method of the display device according to the present embodiment, the second layer 162b of the second interlayer-insulating layer 162 having the first step Hd1 in a height difference between the first portion 1621 and the second portion 1622 is formed by polishing a surface of the insulating layer 160 using the planarization device CD after forming the insulating layer 160 constituting the second interlayer-insulating layer 162 to have a step Hd1a on the surface of the insulating layer 160 without being thickly deposited such that the surface thereof is flat. As such, the second interlayer-insulating layer 162 may be formed to include the first portion 1621 and the second portion 1622 having different heights measured from the surface of the substrate along the first direction Dz, the first portion 1621 may have a flat surface, and the second portion 1622 may also have a flat surface.

Accordingly, the contact holes formed in a relatively large number of insulating layers and having deep depths may be formed in the first portion 1621 of the second interlayer-insulating layer 162 having a relatively low surface height, thereby allowing the contact holes to be formed without defects without increasing the planar areas of the contact holes, and since surfaces of the first portion 1621 and the second portion 1622 of the second interlayer-insulating layer 162 are respectively flat, a conductor formed thereon may be disposed on a flat surface, thereby effectively preventing disconnection of the conductor.

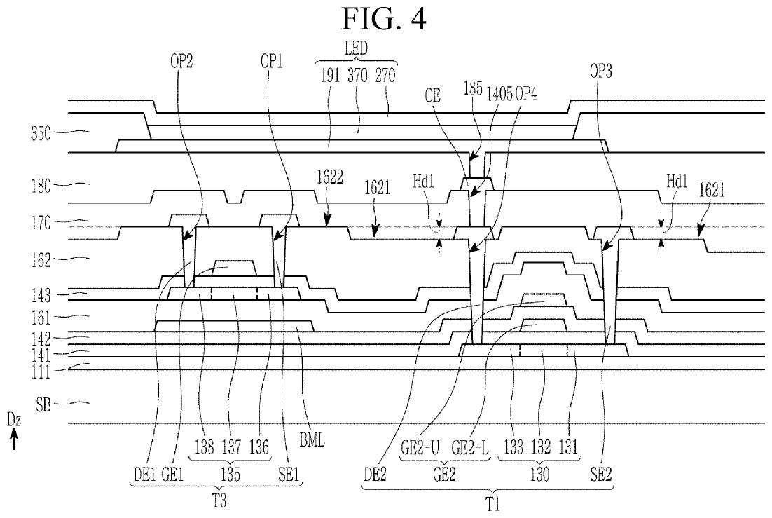

Hereinafter, a display device according to another embodiment will now described with reference to FIG. 4. FIG. 4 illustrates a cross-sectional view of a display device according to another embodiment.

Referring to FIG. 4, the display device according to the present embodiment is similar to the display device according to the embodiment previously described with reference to FIG. 1 and FIG. 2. A detailed description of same constituent elements will be omitted.

Referring to FIG. 4, unlike the display device according to the embodiment previously described with reference to FIG. 1 and FIG. 2, the second interlayer-insulating layer 162 may be formed as a single layer, and the second interlayer-insulating layer 162 may include a silicon oxide.

The second interlayer-insulating layer 162 may include a first portion 1621 and a second portion 1622 having different heights measured from a surface of the substrate along the first direction Dz, and for example, the first portion 1621 of the second interlayer-insulating layer 162 may be a portion having a relatively low surface height, and the second portion 1622 of the second interlayer-insulating layer 162 may be a portion having a relatively high surface height.

The first portion 1621 and the second portion 1622 of the second interlayer-insulating layer 162 may have a height difference, i.e., a first step Hd1.

A surface of the first portion 1621 of the second interlayer-insulating layer 162 may be flat, and a surface of the second portion 1622 of the second interlayer-insulating layer 162 may also be flat.

As such, in accordance with the display device according to the present embodiment, a surface of the second interlayer-insulating layer 162, which is an organic insulating layer in which a contact hole is formed, has the first portion 1621 and the second portion 1622 having the first step Hd1, and each surface of the first portion 1621 and the second portion 1622 may be planar. Accordingly, contact holes may be formed without errors in a plurality of insulating layers without increasing planar areas thereof, and disconnection of electrodes disposed on the second interlayer-insulating layer 162 may be effectively prevented.

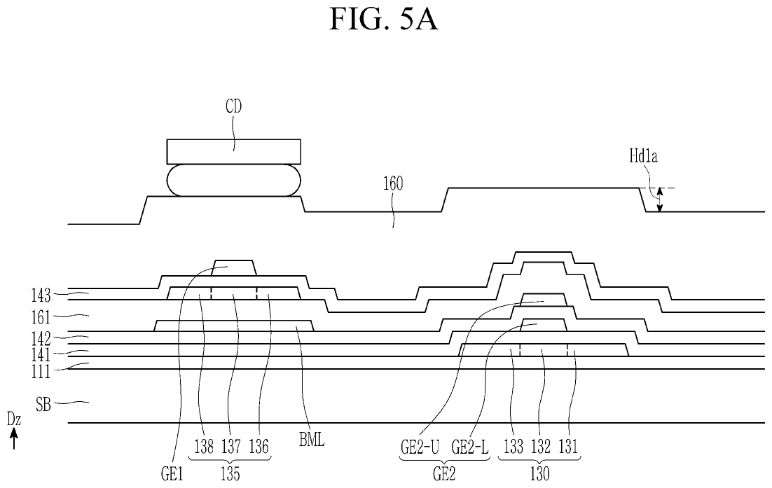

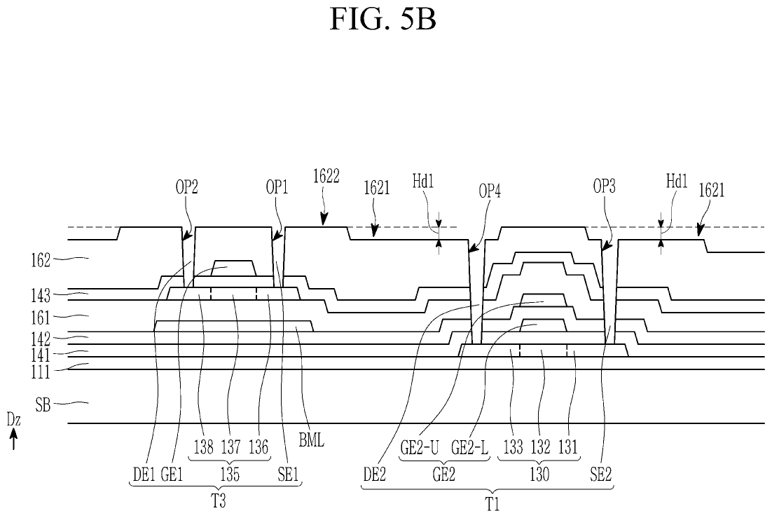

Hereinafter, a manufacturing method of a display device according to another embodiment will be described with reference to FIG. 5A and FIG. 5B together with FIG. 4. FIG. 5A and FIG. 5B illustrate cross-sectional views showing a manufacturing method of a display device according to another embodiment.

As illustrated in FIG. 5A, an insulating layer 160 having a step Hd1a is deposited on the substrate SB on which the second semiconductor 130, the second gate lower electrode GE2-L, the second gate upper electrode GE2-U, the metal layer BML, the first semiconductor 135, and the first gate electrode GE1 are formed, and a surface of the insulating layer 160 is polished by using the planarization device CD.

As illustrated in FIG. 5B, the second interlayer-insulating layer 162 having the first step Hd1 having a height difference between the first portion 1621 and the second portion 1622 is formed, and the first contact hole OP1 and the second contact hole OP2 are formed in the second interlayer-insulating layer 162 and the third gate insulating layer 143, and the third contact hole OP3 and a fourth contact hole OP4 are formed in the second interlayer-insulating layer 162, the third gate insulating layer 143, the first interlayer-insulating layer 161, the second gate insulating layer 142, and the first gate insulating layer 141.

More specifically, the second interlayer-insulating layer 162 may include the first portion 1621 and the second portion 1622 having different heights measured from a surface of the substrate along the first direction Dz, and for example, the first portion 1621 of the second interlayer-insulating layer 162 may be a portion having a relatively low surface height, and the second portion 1622 of the second interlayer-insulating layer 162 may be a portion having a relatively high surface height. The first portion 1621 and the second portion 1622 of the second interlayer-insulating layer 162 may have a height difference, i.e., a first step Hd1. In addition, a surface of the first portion 1621 of the second interlayer-insulating layer 162 may be flat, and a surface of the second portion 1622 of the second interlayer-insulating layer 162 may also be flat.

The third contact hole OP3 and the fourth contact hole OP4 formed in the relatively large number of insulating layers 141, 142, 161, 143, and 162 are formed in the first portion 1621 of the second interlayer-insulating layer 162, having the relatively low surface height.

Accordingly, the third contact hole OP3 and the fourth contact hole OP4 may be formed without defects even while planar areas of the third contact hole OP3 and the fourth contact hole OP4 formed in the relatively large number of insulating layers 141, 142, 161, 143, and 162 are not widened.

Next, a first source electrode SE1 and a first drain electrode DE1, and a second source electrode SE2 and a second drain electrode DE2, may be formed on the second interlayer-insulating layer 162. Since the first portion 1621 and the second portion 1622 of the second interlayer-insulating layer 162 each have a flat surface, the second source electrode SE2 and the second drain electrode DE2 and the first source electrode SE1 and the first drain electrode DE1 formed thereon may be formed on the flat surface, thereby effectively preventing disconnection of the second source electrode SE2 and the second drain electrode DE2, the first source electrode SE1, and the first drain electrode DE1.

Next, the first insulating layer 170 is formed on the first source electrode SE1, the first drain electrode DE1, the second source electrode SE2, and the second drain electrode DE2, the connection electrode CE, the data line 171, and the driving voltage line 172 are formed on the first insulating layer 170, the second insulating layer 180 is formed on the connection electrode CE and the data line 171, the pixel electrode 191 is formed on the second insulating layer 180, the pixel defining layer 350 is formed on the pixel electrode 191, the light emission layer 370 is formed in the pixel opening 365 of the pixel defining layer 350, and the common electrode 270 is formed on the emission layer 370 and the pixel defining layer 350 to form the display device illustrated in FIG. 2.

In accordance with the manufacturing method of the display device according to the present embodiment, the second interlayer-insulating layer 162 having the first step Hd1 in a height difference between the first portion 1621 and the second portion 1622 is formed by polishing a surface of the insulating layer 160 using the planarization device CD after forming the insulating layer 160 constituting the second interlayer-insulating layer 162 to have a step Hd1a on the surface of the insulating layer 160 without being thickly deposited such that the surface thereof is flat. As such, the second interlayer-insulating layer 162 may be formed to include the first portion 1621 and the second portion 1622 having different heights measured from the surface of the substrate along the first direction Dz, the first portion 1621 may have a flat surface, and the second portion 1622 may also have a flat surface.

Accordingly, the contact holes formed in a relatively large number of insulating layers and having deep depths may be formed in the first portion 1621 of the second interlayer-insulating layer 162 having a relatively low surface height, thereby allowing the contact holes to be formed without defects without increasing the planar areas of the contact holes, and since surfaces of the first portion 1621 and the second portion 1622 of the second interlayer-insulating layer 162 are respectively flat, a conductor formed thereon may be disposed on a flat surface, thereby effectively preventing disconnection of the conductor.

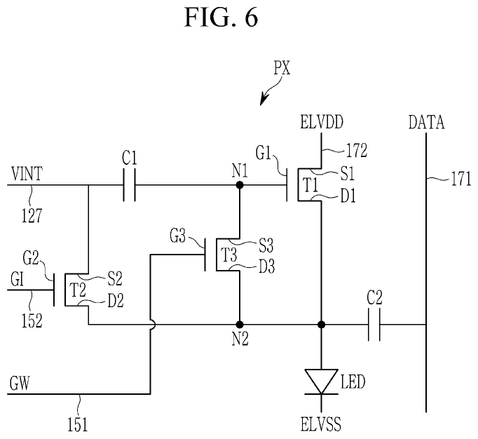

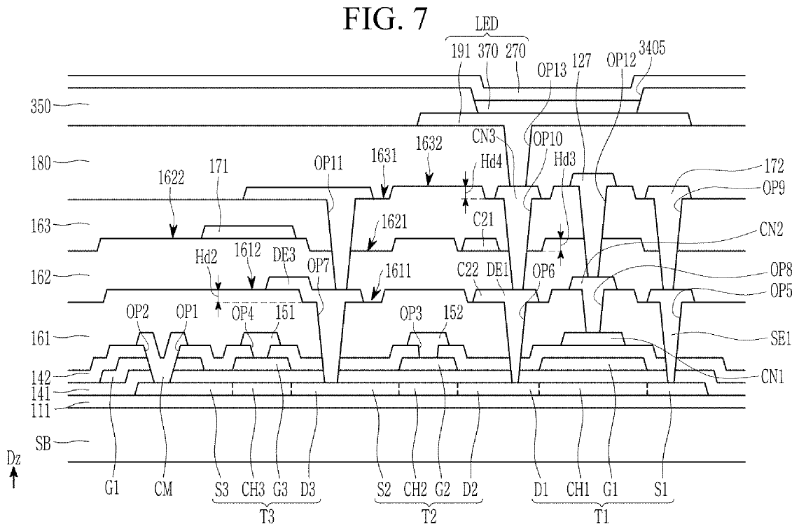

A display device according to an embodiment will now described with reference to FIG. 6 and FIG. 7. FIG. 6 illustrates a circuit diagram of one pixel of a display device according to another embodiment, and FIG. 7 illustrates a cross-sectional view showing a portion of one pixel of a display device according to an embodiment.

Referring to FIG. 6, the pixel PX include three transistors T1, T2, and T3, two capacitors C1 and C2, and a light emitting diode LED, which are directly or indirectly connected to signal lines 151, 153, 171, 172, and 127,

The signal lines 151, 153, 171, 172, and 127 may include the first scan line 151 transferring the gate signal GW, the second scan line 152 transmitting a scan signal GI, the data line 171 transferring the data voltage DATA, the driving voltage line 172 transferring the driving voltage ELVDD, and the initialization voltage line 127 transferring the initialization voltage VINT.

The transistors T1, T2, and T3 include a first transistor T1, a second transistor T2, and a third transistor T3. The transistors T1, T2, and T3 may include N-type transistors. However, alternatively, the transistors T1, T2, and T3 may include P-type transistors, or may include N-type transistors and P-type transistors.

The first transistor T1 includes a first gate electrode G1 (also referred to as a control electrode) connected to a first node N1, a first source electrode S1 (also referred to as a first electrode or an input electrode) connected to the driving voltage line 172, and a first drain electrode D1 connected to a second node N2 (also referred to as a second electrode or an output electrode). The first transistor T1 is a transistor that outputs a driving current to the light emitting diode LED, and may be referred to as a driving transistor.

The driving voltage ELVDD applied to the first source electrode S1 through the driving voltage line 172 may have a high voltage of a high level and a low voltage of a low level.

The second transistor T2 includes a second gate electrode G2 connected to the second scan line 152, a second source electrode S2 connected to the initialization voltage line 127, and a second drain electrode D2 connected to a second node N2. The scan signal GI applied to the second gate electrode G2 through the second scan line 152 may have a high voltage and a low voltage for turning the second transistor T2 on and off.

The initialization voltage VINT applied through the initialization voltage line 127 may have a high voltage for turning on the first transistor T1, a low voltage for initializing an anode of the light emitting diode LED, and a reset voltage for resetting the anode. The reset voltage may be lower than or higher than a low voltage of the initialization voltage VINT.

The third transistor T3 includes a third gate electrode G3 connected to the first scan line 151, a third source electrode S3 connected to the first node N1, and a third drain electrode D3 connected to the second node N2.

The gate signal GW applied to the gate electrode G3 through the first scan line 151 may have a high voltage and a low voltage for turning the third transistor T3 on and off.

The first capacitor C1 is connected between the initialization voltage line 127 and the first node N1. The first capacitor C1 may store a voltage of the first node N1. The first capacitor C1 may be referred to as a storage capacitor.

The second capacitor C2 is connected between the second node N2 and the data line 171. The second capacitor C2 may write the data voltage DATA transferred through the data line 171. The second capacitor C2 may be referred to as a programming capacitor.

The first and second capacitors C1 and C2 may be connected in series by the third transistor T3, and the data voltage DATA is distributed by the first and second capacitors C1 and C2 to be applied to the first node N1.

The light emitting diode LED includes an anode connected to the second node N2 and a cathode to which a common voltage ELVSS is applied. When the first transistor T1 is turned on, a driving current corresponding to the data voltage DATA applied to the first node N1 may flow through the light emitting diode LED, and the light emitting diode LED may emit light with a predetermined luminance.

Previously, a case has been described that one pixel PX includes three transistors T1 to T3 and two capacitors C1 and C2, but the embodiment according to the invention is not limited thereto, and the number of transistors, the number of capacitors, and their connection relationship may be variously changed.

According to the embodiment illustrated in FIG. 7, for convenience of description, the first to third transistors T1 to T3 and the light emitting diode LED connected to the first transistor T1 are mainly illustrated, but the embodiment according to the invention is not limited thereto, and as described above with reference to FIG. 6, other transistors and capacitors may be included.

Referring to FIG. 7 along with FIG. 6, the buffer layer 111 may be disposed on the substrate SB, and semiconductor layers C1, C2, C3, S1, S2, S3, D1, D2, and D3 may be disposed on the buffer layer 111.

The semiconductor layers C1, C2, C3, S1, S2, S3, D1, D2, and D3 may include a first channel region CHL a first source region S1, and a first drain region D1 of the first transistor T1, a second channel region CH2, a second source region S2, and a second drain region D2 of the second transistor T2, and a third channel region CH3, a third source region S3, and a third drain region D3 of the third transistor T3.

The semiconductor layers C1, C2, C3, S1, S2, S3, D1, D2, and D3 may include semiconductor materials such as polycrystalline silicon, amorphous silicon, and an oxide semiconductor.

A gate insulating layer 141 may be disposed on the semiconductor layers C1, C2, C3, S1, S2, S3, D1, D2, and D3, and a first gate conductor including a first gate electrode G1, a second gate electrode G2, and a third gate electrode G3 may be disposed on the gate insulating layer 141.

The first gate electrode G1, the second gate electrode G2, and the third gate electrode G3 may each have a substantially rectangular shape, and may have an island shape.

A second gate insulating layer 142 may be disposed on the first gate conductor.

A second gate conductor including a first scan line 151, a second scan line 152, a first connection electrode CN1, and a connection member CM may be disposed on the second gate insulating layer 142.

As described later, the first connection electrode CN1 may be connected to the initialization voltage line 127, and may overlap the first gate electrode G1 in a plan view.

A portion where the first connection electrode CN1 and the first gate electrode G1 overlap each other may form the first capacitor C1 together with the second gate insulating layer 142.

A first contact hole OP1 exposing the third source electrode S3 may be formed in the first gate insulating layer 141 and the second gate insulating layer 142, a second contact hole OP2 exposing the first gate electrode G1 may be formed in the second gate insulating layer 142, and the connection member CM may connect the first gate electrode G1 to the third source electrode S3 in a side contact manner. In the illustrated embodiment, although the first gate electrode G1 is illustrated to be separated into opposite sides, this is for convenience of description, and first gate electrodes G1 are connected to each other.

In the second gate insulating layer 142, a third contact hole OP3 exposing the second gate electrode G2 and a fourth contact hole OP4 exposing the third gate electrode G3 are formed in the second gate insulating layer 142, the first scan line 151 is connected to the third gate electrode G3 through the fourth contact hole OP4 to transfer the gate signal GW, and the second scan line 152 may be connected to the second gate electrode G2 through the third contact hole OP3 to transfer the scan signal GI.

The first interlayer-insulating layer 161 is disposed on the second gate conductor.

The first interlayer-insulating layer 161 may include a first portion 1611 and a second portion 1612 having different heights measured from a surface of the substrate along the first direction Dz, and for example, the first portion 1611 of the first interlayer-insulating layer 161 may be a portion having a relatively low surface height, and the second portion 1612 of the first interlayer-insulating layer 161 may be a portion having a relatively high surface height.

The first portion 1611 and the second portion 1612 of the first interlayer-insulating layer 161 may have a height difference, i.e., a second step Hd2.

A surface of the first portion 1611 of the first interlayer-insulating layer 161 may be flat, and a surface of the second portion 1612 of the first interlayer-insulating layer 161 may also be flat.

A fifth contact hole OP5 and a sixth contact hole OP6 exposing the first source region S1 and the first drain region D1 of the first transistor T1 and a seventh contact hole OP7 exposing the third drain region D3 of the third transistor T3 may be formed in the first portion 1611 of the first interlayer-insulating layer 161, the second gate insulating layer 142, and the first gate insulating layer 141. Although not illustrated, other contact holes may be further formed in the first portion 1611 of the first interlayer-insulating layer 161, the second gate insulating layer 142, and the first gate insulating layer 141.

An eighth contact hole OP8 exposing the first connection electrode CN1 may be formed in the second portion 1612 of the first interlayer-insulating layer 161.

The fifth contact hole OP5, the sixth contact hole OP6, and the seventh contact hole OP7 may be formed in a relatively large number of insulating layers 141, 142, and 161, and the eighth contact hole OP8 may be formed in a relatively small number of insulating layers. However, the fifth contact hole OP5, the sixth contact hole OP6, and the seventh contact hole OP7 formed in the relatively large number of insulating layers 141, 142, and 161 are formed in the first portion 1611 of the first interlayer-insulating layer 161 having a relatively low surface height. Accordingly, thicknesses of the insulating layers 141, 142, and 161 in which the fifth contact hole OP5, the sixth contact hole OP6, and the seventh contact hole OP7 are formed may be reduced, and thus the fifth contact hole OP5, the sixth contact hole OP6, and the seventh contact hole OP7 may be formed without defects without increasing planar areas of the fifth contact hole OP5, the sixth contact hole OP6, and the seventh contact hole OP7 formed in the relatively large number of insulating layers 141, 142, and 161.

A first data conductor including the first source electrode SE1 and the first drain electrode DE1 connected to the first source region S1 and the first drain region D1 of the first transistor T1 through the fifth contact hole OP5 and the sixth contact hole OP6, respectively, the third drain electrode DE3 connected to the third drain region D3 of the third transistor T3 through the seventh contact hole OP7, and the second connection electrode CN2 connected to the first connection electrode CN1 through the eighth contact hole OP8 is disposed on the first interlayer-insulating layer 161.

As such, in accordance with the display device according to the present embodiment, a surface of the first interlayer-insulating layer 161, which is an organic insulating layer in which a contact hole is formed, has the first portion 1611 and the second portion 1612 having the second step Hd2, and each surface of the first portion 1611 and the second portion 1612 may be planar. Accordingly, contact holes may be formed without errors in a plurality of insulating layers without increasing planar areas thereof, and disconnection of electrodes formed on the first interlayer-insulating layer 161 may be effectively prevented.

In the illustrated embodiment, although it has been described that the first interlayer-insulating layer 161 is formed as a single layer, the present embodiment is not limited thereto, and similar to the second interlayer-insulating layer 162 of the display device according to the embodiment described with reference to FIG. 2, the first interlayer-insulating layer 161 may be formed to include a first layer including a silicon nitride and a second layer including a silicon oxide, and the first layer including the silicon nitride may serve as a stopper in a planarization process of the second layer including the silicon oxide. Accordingly, a portion of the second portion 1612 of the first interlayer-insulating layer 161 having a relatively high surface height may have the same height as that of the first layer.

The second interlayer-insulating layer 162 is disposed on the first data conductor. The second interlayer-insulating layer 162 may include an insulating material, and for example, the second interlayer-insulating layer 162 may include a silicon oxide.

The second interlayer-insulating layer 162 may include a first portion 1621 and a second portion 1622 having different heights measured from a surface of the substrate along the first direction Dz, and for example, the first portion 1621 of the second interlayer-insulating layer 162 may be a portion having a relatively low surface height, and the second portion 1622 of the second interlayer-insulating layer 162 may be a portion having a relatively high surface height.

The first portion 1621 and the second portion 1622 of the second interlayer-insulating layer 162 may have a height difference, i.e., a third step Hd3.

In the illustrated embodiment, although a case has been described that the second interlayer-insulating layer 162 is formed as a single layer, the present embodiment according to the invention is not limited thereto, and similar to the second interlayer-insulating layer 162 of the display device according to the embodiment described with reference to FIG. 2, the second interlayer-insulating layer 162 may include a first layer including a silicon nitride and a second layer including a silicon oxide, and the first layer including the silicon nitride may serve as a stopper in a planarization process of the second layer including the silicon oxide in another embodiment. Accordingly, a portion of the second portion 1622 of the second interlayer-insulating layer 162 having a relatively high surface height may have the same height as the first layer 162a.

A second data conductor including the data line 171 may be disposed on the second interlayer-insulating layer 162 (See FIG. 7). The data line 171 may include a first electrode C21 of the extended second capacitor C2. An extended portion of the first drain electrode DE1 may constitute a second electrode C22 of the second capacitor C2, and the first electrode C21 and the second electrode C22 may overlap each other with the second interlayer-insulating layer 162 therebetween to form a portion of the second capacitor C2. In this case, the first electrode C21 of the second capacitor C2 extended from the data line 171 is disposed on the first portion 1621 of the second interlayer-insulating layer 162 having a relatively low surface height, and accordingly, since a thickness of the first portion 1621 of the second interlayer-insulating layer 162 disposed between the first electrode C21 and the second electrode C22 is thin, a capacitance of the second capacitor C2 may be increased.

A third interlayer-insulating layer 163 is disposed on the second data conductor. The third interlayer-insulating layer 163 may include a first portion 1631 and a second portion 1632 having different heights measured from a surface of the substrate along the first direction Dz, and for example, the first portion 1631 of the third interlayer-insulating layer 163 may be a portion having a relatively low surface height, and the second portion 1632 of the third interlayer-insulating layer 163 may be a portion having a relatively high surface height.

The first portion 1631 and the second portion 1632 of the third interlayer-insulating layer 163 may have a height difference, i.e., a fourth step Hd4.

A contact hole OP9 and a tenth contact hole OP10 exposing the first source electrode SE1 and the first drain electrode DE1 of the first transistor T1 and an eleventh contact hole OP11 exposing the third drain electrode DE3 of the third transistor T3 may be formed in the second interlayer-insulating layer 162 and the third interlayer-insulating layer 163. In addition, a twelfth contact hole OP12 exposing the second connection electrode CN2 is formed in the second interlayer-insulating layer 162 and the third interlayer-insulating layer 163.

The ninth contact hole OP9, the tenth contact hole OP10, and the eleventh contact hole OP11 are formed in the first portion 1631 of the third interlayer-insulating layer 163 having a relatively low surface height, and accordingly, depths of the ninth contact hole OP9, the tenth contact hole OP10, and the eleventh contact hole OP11 are reduced. Accordingly, the ninth contact hole OP9, the tenth contact hole OP10, and the eleventh contact hole OP11 may be formed without defects without increasing planar areas of the ninth contact hole OP9, the tenth contact hole OP10, and the eleventh contact hole OP11.

In the illustrated embodiment, although it has been described that the third interlayer-insulating layer 163 is formed as a single layer, the present embodiment is not limited thereto, and similar to the second interlayer-insulating layer 162 of the display device according to the embodiment described with reference to FIG. 2, the third interlayer-insulating layer 163 may be formed to include a first layer including a silicon nitride and a second layer including a silicon oxide, and the first layer including the silicon nitride may serve as a stopper in a planarization process of the second layer including the silicon oxide. Accordingly, a portion of the second portion 1632 of the third interlayer-insulating layer 163 having a relatively high surface height may have the same height as that of the first layer.

A third data conductor including an initialization voltage line 127, a driving voltage line 172, a third connection electrode CN3, and a fourth connection electrode CN4 is disposed on the third interlayer-insulating layer 163.

The driving voltage line 172 is connected to the first source electrode SE1 of the first transistor T1 through the ninth contact hole OP9, the third connection electrode CN3 is connected to the first drain electrode DE1 of the first transistor T1 through the tenth contact hole OP10, and the fourth connection electrode CN4 is connected to the third drain electrode DE3 of the third transistor T3 through the eleventh contact hole OP11.

The initialization voltage line 127 is connected to the second connection electrode CN2 through the twelfth contact hole OP12 to transfer the initialization voltage VINT to the first gate electrode G1 of the first transistor T1.

The fourth connection electrode CN4 connected to the third drain electrode DE3 of the third transistor T3 overlaps the data line 171 with the third interlayer-insulating layer 163 therebetween to constitute a portion of the second capacitor C2.

An insulating layer 180 is disposed on the third data conductor, and has a thirteenth contact hole OP13 exposing the third connection electrode CN3 connected to the first drain electrode DE1 of the first transistor T1.

A pixel electrode 191 connected to the third connection electrode CN3 through the thirteenth contact hole OP13 may be disposed on the insulating layer 180. The pixel electrode 191 may be connected to the first drain electrode DE1 of the first transistor T1 through the third connection electrode CN3.

A pixel defining layer 350 may be disposed on the pixel electrode 191. A pixel opening 365 may be formed in the pixel defining layer 350, and the pixel opening 365 of the pixel defining layer 350 may overlap the pixel electrode 191. An emission layer 370 may be disposed in the pixel opening 365 of the pixel defining layer 350.

A common electrode 270 may be disposed on the emission layer 370 and the pixel defining layer 350.

The pixel electrode 191, the emission layer 370, and the common electrode 270 may constitute a light emitting diode LED. Herein, the pixel electrode 191 may be an anode which is a hole-injection electrode, and the common electrode 270 may be a cathode which is an electron-injection electrode. However, the embodiment is not limited thereto, and the pixel electrode 191 may be a cathode and the common electrode 270 may be an anode depending on a driving method of an organic light emitting diode device.

When holes and electrons are injected from the pixel electrode 191 and the common electrode 270 into the emission layer 370, excitons formed by combining the injected holes and electrons are emitted when they fall from an excited state to a ground state.

Although not illustrated, an encapsulation layer (not illustrated) may be disposed on the common electrode 270, and the encapsulation layer may cover not only an upper surface but also a side surface of the pixel to encapsulate a pixel portion. The encapsulation layer may include a plurality of layers, and may be formed as a composite layer including both an inorganic layer and an organic layer.

As such, in accordance with the display device according to an embodiment, surfaces of the first interlayer-insulating layer 161, the second interlayer-insulating layer 162, and the third interlayer-insulating layer 163, which are insulating layers where contact holes are formed, may each have a first portion (1611, 1621, and 1631) and a second portion (1612,1622, and 1632) with steps from each other, and each of the surfaces of the first portions 1611, and 1621, 1631 and the second portion 1612, 1622, and 1632 may be flat. Accordingly, contact holes may be formed without errors in a plurality of insulating layers without increasing planar areas thereof, and disconnection of wires and electrodes formed on the insulating layer may be effectively prevented. In addition, electrodes constituting a capacitor by overlapping each other with an interlayer-insulating layer therebetween may overlap each other with the relatively low-height first portions 1611, 1621, and 1631 therebetween, thereby increasing a capacitance of the capacitor.

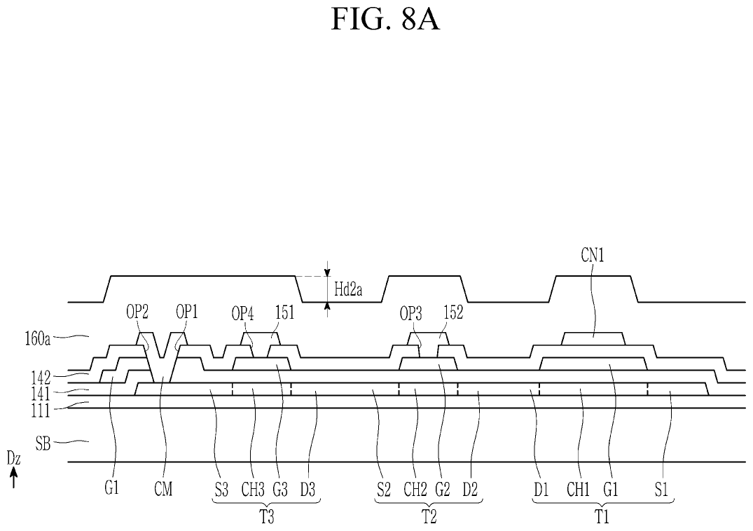

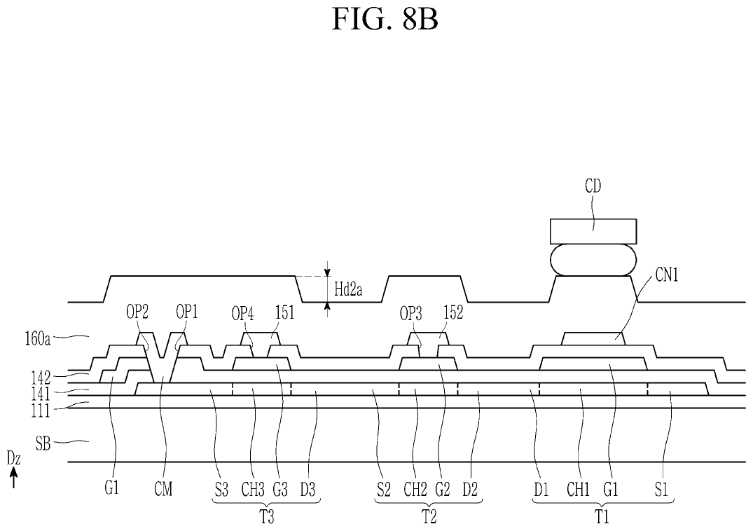

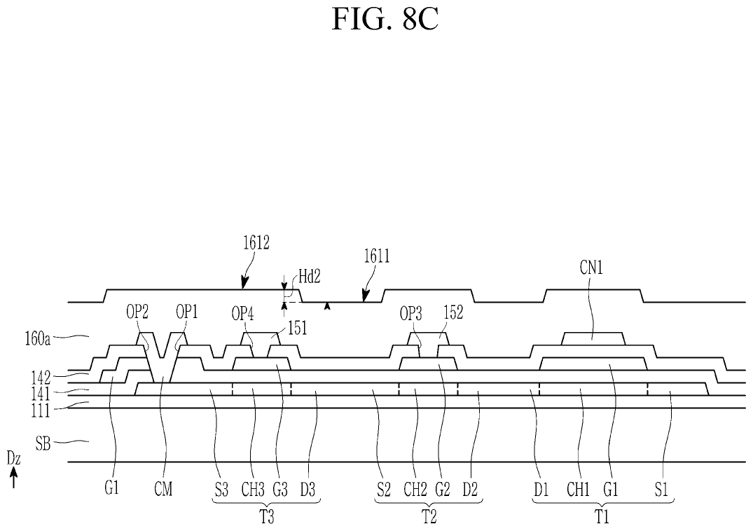

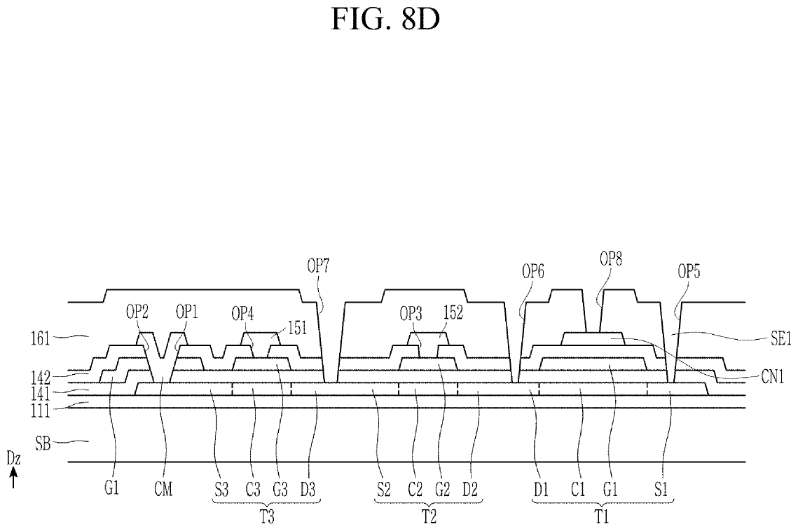

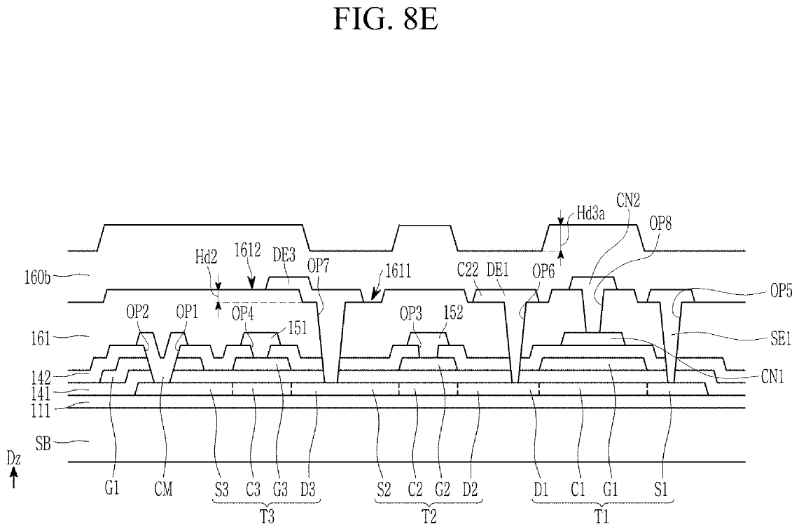

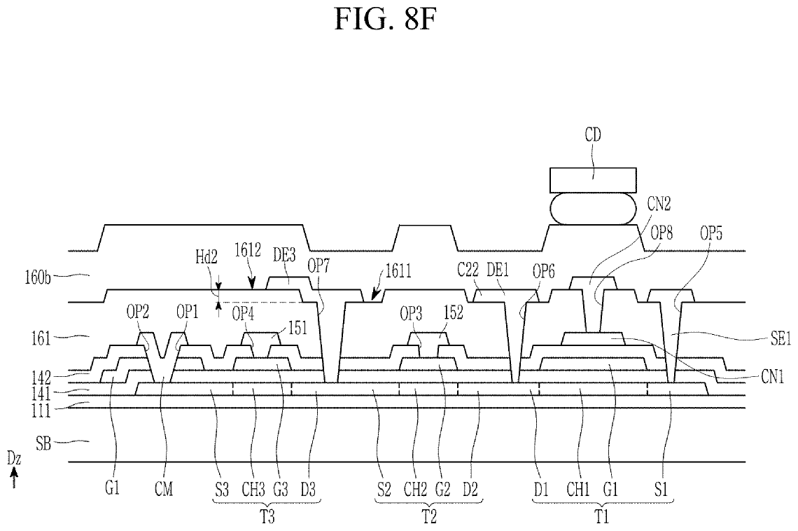

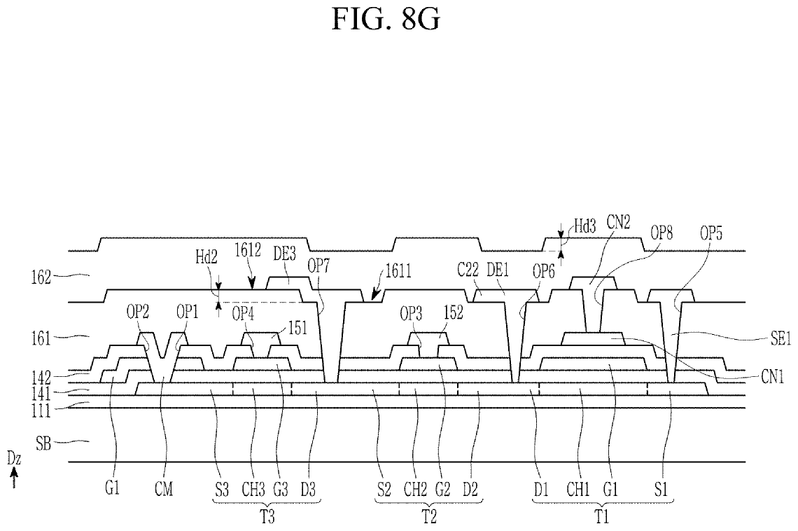

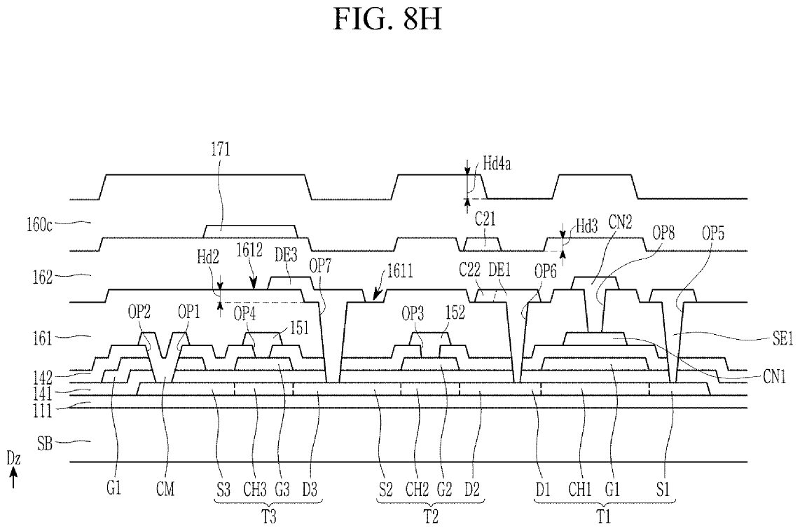

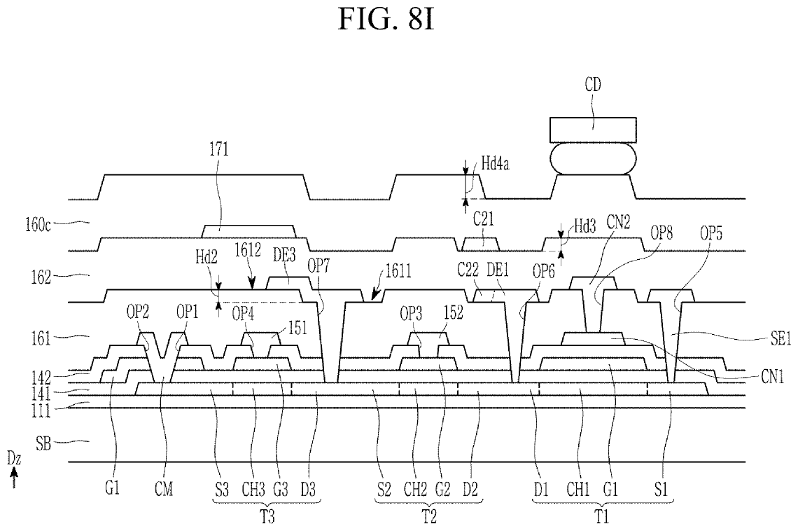

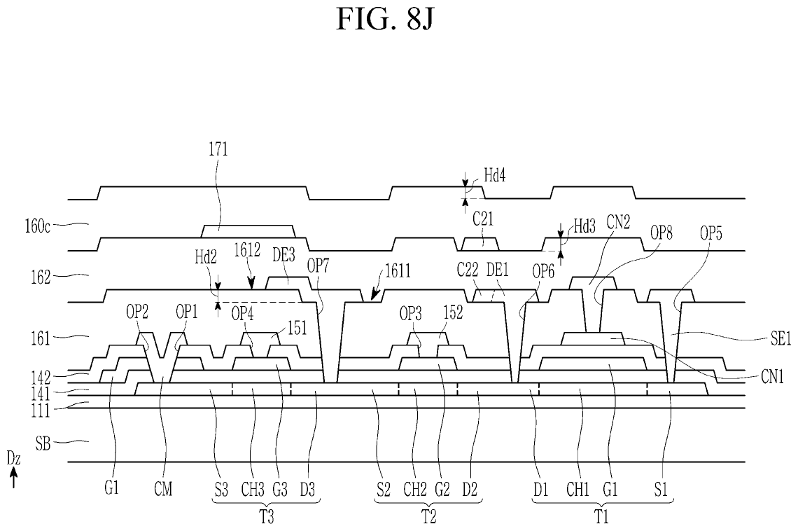

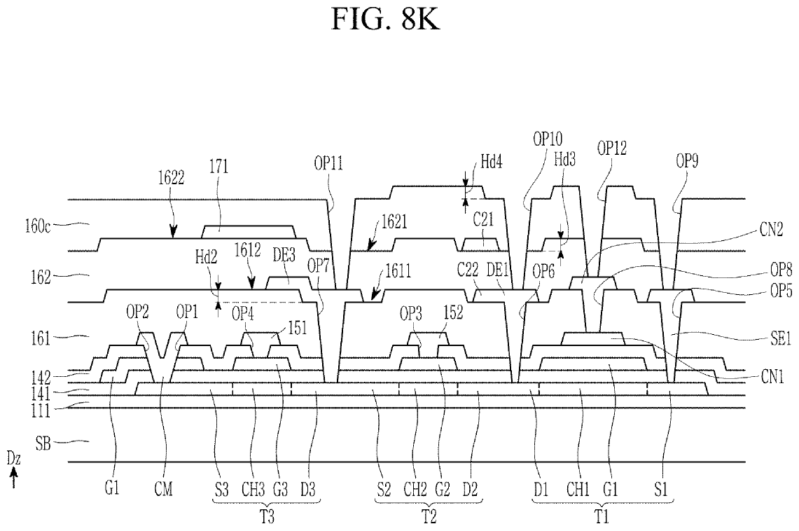

Hereinafter, a manufacturing method of a display device according to another embodiment will be described with reference to FIG. 8A to FIG. 8K together with FIG. 7. FIG. 8A to FIG. 8K illustrate cross-sectional views showing a manufacturing method of a display device according to another embodiment.

As illustrated in FIG. 8A, a buffer layer 111 is formed on the substrate SB, semiconductor layers C1, C2, C3, 51, S2, S3, D1, D2, and D3 are formed on the buffer layer 111, a gate insulating layer 141 is formed on the semiconductor layers C1, C2, C3, S1, S2, S3, D1, D2, and D3, a first gate conductor including a first gate electrode G1, a second gate electrode G2, and a third gate electrode G3 is formed on the gate insulating layer 141, a second gate insulating layer 142 on the first gate conductor, a second gate conductor including a first scan line 151, a second scan line 152, a first connection line CN1, a connection member CM is formed on the second gate insulating layer 142, and an insulating layer 160a constituting the first interlayer-insulating layer 161 is deposited on the second gate conductor.

The insulating layer 160a may have a different height measured from the surface of the substrate along the first direction Dz depending on a position thereof, and a surface of the insulating layer 160a may have a step Hd2a that is larger than the second step Hd2 of the first interlayer-insulating layer 161.

As the surface of the insulating layer 160a is polished by using the planarization device CD as illustrated in FIG. 8B, the first portion 1611 and the second portion 1612 having different heights measured from the surface of the substrate along the first direction Dz are included as illustrated in FIG. 8C, and the first interlayer-insulating layer 161 is formed such that the first portion 1611 and the second portion 1612 have the second step Hd2. A surface of the first portion 1611 of the first interlayer-insulating layer 161 is formed to be flat, and a surface of the second portion 1612 of the first interlayer-insulating layer 161 is also formed to be flat.

In the illustrated embodiment, although it has been described that the first interlayer-insulating layer 161 is formed as a single layer, the present embodiment is not limited thereto, and similar to the second interlayer-insulating layer 162 in accordance with the manufacturing method of the display device according to the embodiment described with reference to FIG. 3A to FIG. 3D, the first interlayer-insulating layer 161 may be formed to include a first layer including a silicon nitride and a second layer including a silicon oxide, and the first layer including the silicon nitride may serve as a stopper in a planarization process of the second layer including the silicon oxide. Accordingly, a portion of the second portion 1612 of the first interlayer-insulating layer 161 having a relatively high surface height may be formed to have the same height as that of the first layer.

Referring to FIG. 8D, a fifth contact hole OP5 and a sixth contact hole OP6 exposing the first source region S1 and the first drain region D1 of the first transistor T1 and a seventh contact hole OP7 exposing the third drain region D3 of the third transistor T3 are formed in the first portion 1611 of the first interlayer-insulating layer 161, the second gate insulating layer 142, and the first gate insulating layer 141, and an eighth contact hole OP8 exposing the first connection electrode CN1 is formed in the second portion 1612 of the first interlayer-insulating layer 161.

As such, the fifth contact hole OP5, the sixth contact hole OP6, and the seventh contact hole OP7 that are formed to have deep depths in a relatively large number of insulating layers 141, 142, and 161 may be formed in the first portion 1611 of the first interlayer-insulating layer 161 having a relatively low surface height, to reduce thicknesses of the insulating layers 141, 142, and 161 in which the fifth contact hole OP5, the sixth contact hole OP6, and the seventh contact hole OP7 are formed, and thus the fifth contact hole OP5, the sixth contact hole OP6, and the seventh contact hole OP7 may be formed without defects without increasing planar areas of the fifth contact hole OP5, the sixth contact hole OP6, and the seventh contact hole OP7 formed in the relatively large number of insulating layers 141, 142, and 161.

As illustrated in FIG. 8E, a first data conductor including the first source electrode SE1 and the first drain electrode DE1 connected to the first source region S1 and the first drain region D1 of the first transistor T1 through the fifth contact hole OP5 and the sixth contact hole OP6, the third drain electrode DE3 connected to the third drain region D3 of the third transistor T3 through the seventh contact hole OP7, and the second connection electrode CN2 connected to the first connection electrode CN1 through the eighth contact hole OP8 is disposed on the first interlayer-insulating layer 161, and an insulating layer 160b is deposited.

The insulating layer 160b may have a different height measured from the surface of the substrate along the first direction Dz depending on a position thereof, and a surface of the insulating layer 160b may have a step Hd3a that is larger than the third step Hd3 of the second interlayer-insulating layer 162.

As the surface of the insulating layer 160b is polished by using the planarization device CD as illustrated in FIG. 8F, the first portion 1621 and the second portion 1622 having different heights measured from the surface of the substrate along the first direction Dz are included as illustrated in FIG. 8G, and the second interlayer-insulating layer 162 is formed such that the first portion 1621 and the second portion 1622 have the third step Hd3. An upper surface of the first portion 1621 of the second interlayer-insulating layer 162 is formed to be flat, and a surface of the second portion 1622 of the second interlayer-insulating layer 162 is also formed to be flat.

More specifically, the second interlayer-insulating layer 162 may include a first portion 1621 and a second portion 1622 having different surface heights, and the first portion 1621 and the second portion 1622 of the second interlayer-insulating layer 162 may be formed to have a height difference, i.e., a third step Hd3.

In the illustrated embodiment, although it has been described that the second interlayer-insulating layer 162 is formed as a single layer, the present embodiment is not limited thereto, and similar to the second interlayer-insulating layer 162 in accordance with the manufacturing method of the display device according to the embodiment described with reference to FIG. 3A to FIG. 3D, the second interlayer-insulating layer 162 may be formed to include a first layer including a silicon nitride and a second layer including a silicon oxide, and the first layer including the silicon nitride may serve as a stopper in a planarization process of the second layer including the silicon oxide. Accordingly, a portion of the second portion 1622 of the second interlayer-insulating layer 162 having a relatively high surface height may be formed to have the same height as that of the first layer.

Referring to FIG. 8H, a second data conductor including the data line 171 and the first electrode C21 of the second capacitor C2 extended from the data line 171 is formed on the second interlayer-insulating layer 162, and an insulating layer 160c is deposited thereon.

In this case, the first electrode C21 of the second capacitor C2 extended from the data line 171 is formed on the first portion 1621 of the second interlayer-insulating layer 162 having a relatively low surface height, and accordingly, since a thickness of the first portion 1621 of the second interlayer-insulating layer 162 disposed between the first electrode C21 and the second electrode C22 is thin, capacitance of the second capacitor C2 may be increased.

The insulating layer 160c may have a different height measured from the surface of the substrate along the first direction Dz depending on a position thereof, and a surface of the insulating layer 160c may have a step Hd4a that is larger than the fourth step Hd4 of the third interlayer-insulating layer 163.

As the surface of the insulating layer 160c is polished by using the planarization device CD as illustrated in FIG. 81, the first portion 1631 and the second portion 1632 having different heights measured from the surface of the substrate along the first direction Dz are included as illustrated in FIG. 8J, and the third interlayer-insulating layer 163 is formed such that the first portion 1631 and the second portion 1632 have the fourth step Hd4. A surface of the first portion 1631 of the third interlayer-insulating layer 163 is formed to be flat, and a surface of the second portion 1632 of the third interlayer-insulating layer 163 is also formed to be flat.

As illustrated in FIG. 8K, the ninth contact hole OP9 and the tenth contact hole OP10 exposing the first source electrode SE1 and the first drain electrode DE1 of the first transistor T1 and the eleventh contact hole OP11 exposing the third drain electrode DE3 of the third transistor T3 are formed in the second interlayer-insulating layer 162 and the third interlayer-insulating layer 163, and the twelfth contact hole OP12 exposing the second connection electrode CN2 is formed in the second interlayer-insulating layer 162 and the third interlayer-insulating layer 163.

In this case, the ninth contact hole OP9, the tenth contact hole OP10, and the eleventh contact hole OP11 are formed in the first portion 1631 of the third interlayer-insulating layer 163 having a relatively low surface height, and accordingly, depths of the ninth contact hole OP9, the tenth contact hole OP10, and the eleventh contact hole OP11 are reduced. Accordingly, the ninth contact hole OP9, the tenth contact hole OP10, and the eleventh contact hole OP11 may be formed without defects without increasing planar areas of the ninth contact hole OP9, the tenth contact hole OP10, and the eleventh contact hole OP11.

In the illustrated embodiment, although it has been described that the third interlayer-insulating layer 163 is formed as a single layer, the present embodiment is not limited thereto, and similar to the second interlayer-insulating layer 162 in accordance with the manufacturing method of the display device according to the embodiment described with reference to FIG. 3A to FIG. 3D, the third interlayer-insulating layer 163 may be formed to include a first layer including a silicon nitride and a second layer including a silicon oxide, and the first layer including the silicon nitride may serve as a stopper in a planarization process of the second layer including the silicon oxide.

Accordingly, a portion of the second portion 1632 of the third interlayer-insulating layer 163 having a relatively high surface height may be formed to have the same height as that of the first layer.

Next, a third data conductor including an initialization voltage line 127, a driving voltage line 172, a third connection electrode CN3, and a fourth connection electrode CN4 is formed on the third interlayer-insulating layer 163, an insulating layer 180 is formed on the third data conductor, a pixel electrode 191 is formed on the insulating layer 180, a pixel defining layer 350 is formed on the pixel electrode 191, an emission layer 370 is formed in the pixel opening 365 of the pixel defining layer 350, and a common electrode 270 is formed on the emission layer 370 and the pixel defining layer 350 to form the display device illustrated in FIG. 7.

As such, in accordance with the manufacturing method of the display device according to the present embodiment, surfaces of the first interlayer-insulating layer 161, the second interlayer-insulating layer 162, and the third interlayer-insulating layer 163, which are insulating layers where contact holes are formed, may each have a first portion (1611, 1621, and 1631) and a second portion (1612, 1622, and 1632) with steps from each other, and each of the surfaces of the first portions 1611, and 1621, 1631 and the second portions 1612, 1622, and 1632 may be formed to be flat. Accordingly, contact holes may be formed without errors in a plurality of insulating layers without increasing planar areas thereof, and disconnection of wires and electrodes disposed on the insulating layer may be effectively prevented. In addition, electrodes constituting a capacitor by overlapping each other with an interlayer-insulating layer therebetween may be formed to overlap each other with the relatively low-height first portions 1611, 1621, and 1631 therebetween, thereby increasing capacitance of the capacitor.

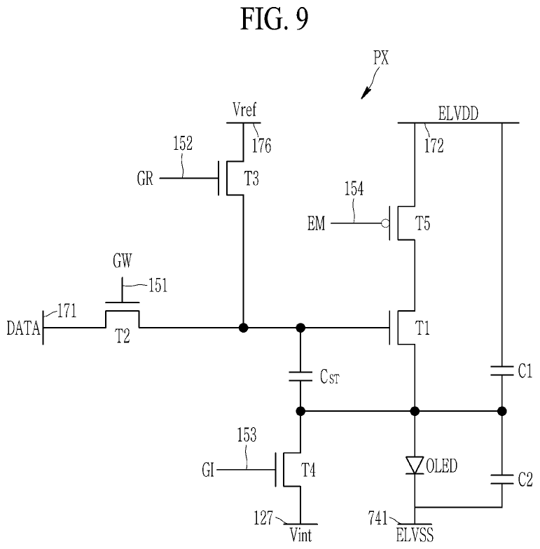

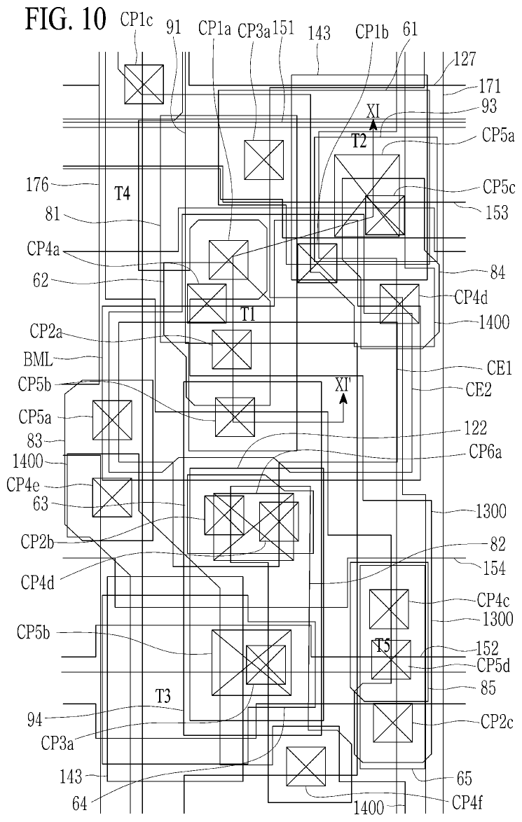

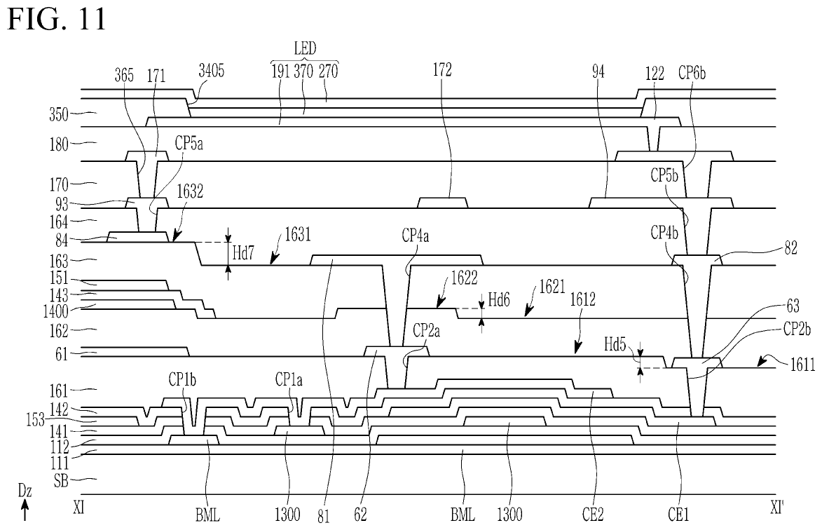

A display device according to another embodiment will now described with reference to FIG. 9 to FIG. 11. FIG. 9 illustrates a circuit diagram of one pixel of a display device according to another embodiment, FIG. 10 illustrates a layout view of one pixel of a display device according to an embodiment, and FIG. 11 illustrates a cross-sectional view taken along line XI-XI′ of FIG. 10.

Referring to FIG. 9, one pixel PX of the display device according to another embodiment includes a plurality of signal lines 151, 152, 153, 154, 127, 171, 172, and 176, and a plurality of transistors T1, T2, T3, T4, and T5, a storage capacitor Cst, a first capacitor C1 and a second capacitor C2, and a light emitting diode LED which are connected thereto.

The signal lines include a data line 171, a driving voltage line 172, a reference voltage line 176, an initialization voltage line 127, a first scan line 151, a second scan line 152, an initialization control line 153, and an emission control line 154.

The data line 171 is a wire for transmitting a data voltage DATA generated by a data driver (not illustrated), and luminance of the organic light emitting diode OLED that emits light is changed depending on the data voltage DATA applied to the pixel PX.

The driving voltage line 172 applies a driving voltage ELVDD, the reference voltage line 176 transfers the reference voltage Vref, the initialization voltage line 127 transfers an initialization voltage Vint for initializing a second storage electrode of the storage capacitor Cst, a second electrode of the driving transistor T1, and an anode of the organic light emitting diode OLED, and the common voltage line 741 applies a common voltage ELVSS to a cathode electrode of the organic light emitting diode OLED. Constant voltages are respectively applied to the driving voltage line 172, the initialization voltage line 127, and the common voltage line 741.

Hereinafter, the transistors T1, T2, T3, T4, and T5 will be described. The transistors T1, T2, T3, T4, and T5 include a driving transistor T1 (also referred to as a first transistor), a second transistor T2, a third transistor T3, a fourth transistor T4, and a fifth transistor T5.

The driving transistor T1 includes a gate electrode connected to a first storage electrode of the storage capacitor Cst, a first electrode connected to a second electrode of the fifth transistor T5, and a second electrode connected to the anode of the organic light emitting diode OLED. The gate electrode of the driving transistor T1 is also connected to a second electrode of the second transistor T2 and a second electrode of the third transistor T3. The second electrode of the driving transistor T1 is also connected to a second electrode of the fourth transistor T4 and a second storage electrode of the storage capacitor Cst. The driving transistor T1 outputs a driving current to the organic light emitting diode OLED depending on a data voltage DATA stored in the storage capacitor Cst. The first electrode of the driving transistor T1 is connected to the driving voltage line 172 via the fifth transistor T5.

The second transistor T2 includes a gate electrode connected to the first scan line 151, a first electrode connected to the data line 171, and a second electrode connected to the gate electrode of the driving transistor T1. The second electrode of the second transistor T2 is also connected to a first electrode of the third transistor T3 and a second storage electrode of the storage capacitor Cst. The second transistor T2 may have a characteristic of an n-type transistor, and may be turned on when a high voltage gate signal GWn is applied to the gate electrode. When the second transistor T2 is turned on, the data voltage DATA supplied through the data line 171 may be transferred to the first storage electrode of the storage capacitor Cst and the gate electrode of the driving transistor T1.

The third transistor T3 includes a gate electrode connected to the second scan line 152, a first electrode connected to the reference voltage line 176, and a second electrode connected to the gate electrode of the driving transistor T1. The second electrode of the third transistor T3 is also connected to the first electrode of the second transistor T2 and the second storage electrode of the storage capacitor Cst. The third transistor T3 may have a characteristic of an n-type transistor, and may be turned on when a high-voltage voltage control signal GRn is applied to the gate electrode. When the third transistor T3 is turned on, a reference voltage Vref from the reference voltage line 176 may be transferred to the first storage electrode of the storage capacitor Cst and the gate electrode of the driving transistor T1.

The fourth transistor T4 includes a gate electrode connected to the initialization control line 153, a first electrode connected to the initialization voltage line 127, and a second electrode connected to the second storage electrode of the storage capacitor Cst. The second electrode of the fourth transistor T4 is also connected to the second electrode of the driving transistor T1 and the anode of the organic light emitting diode OLED. The fourth transistor T4 may have a characteristic of an n-type transistor, and may be turned on when a high-voltage initialization control signal GIn is applied to the gate electrode. When the fourth transistor T4 is turned on, the initialization voltage Vint may be transferred from the initialization voltage line 127 to the second storage electrode of the storage capacitor Cst, the anode of the organic light emitting diode OLED, and the second electrode of the driving transistor T1.

The fifth transistor T5 includes a gate electrode connected to the emission control line 154, a first electrode connected to the driving voltage line 172, and a second electrode connected to the first electrode of the driving transistor T1. The fifth transistor T5 may have a characteristic of a p-type transistor, and may be turned on when a low-voltage emission control signal EMn is applied to the gate electrode. When the fifth transistor T5 is turned on, the driving voltage ELVDD from the driving voltage line 172 may be transferred to the first electrode of the driving transistor T1.

Some of the transistors T1, T2, T3, T4, and T5 included in the pixel PX include semiconductor layers formed of an oxide semiconductor and have the n-type transistor characteristic, and the remaining transistors include semiconductor layers formed of a polycrystalline semiconductor and have the p-type transistor characteristic. Hereinafter, a transistor including an oxide semiconductor is referred to as an “oxide semiconductor transistor”, and a transistor including a polycrystalline semiconductor is referred to as a “polycrystalline semiconductor transistor”.

The storage capacitor Cst includes a first electrode connected to the gate electrode of the driving transistor T1 and a second electrode connected to the second electrode of the fourth transistor T4. The first storage electrode of the storage capacitor Cst is also connected to the second electrode of the second transistor T2 and the second electrode of the third transistor T3. The storage capacitor Cst may store the data voltage DATA supplied through the second transistor T2. The data voltage DATA stored in the storage capacitor Cst determines a magnitude of the driving current by controlling a degree to which the driving transistor T1 is turned on.

The first capacitor C1 may include a first electrode connected to the driving voltage ELVDD and a second electrode connected to the second electrode of the driving transistor T1, and the second capacitor C2 may include a first electrode connected to the second electrode of the driving transistor T1 and a second electrode connected to the common voltage ELVSS.

The light emitting diode LED includes an anode connected to the second electrode of the driving transistor T1 and a cathode to which a common voltage is applied. The light emitting diode LED emits light depending on a driving current outputted from the driving transistor T1 to express gray levels.

Now, an example of one pixel illustrated in FIG. 9 will be described with reference to FIG. 10 and FIG. 11.

Referring to FIG. 10 and FIG. 11, the buffer layer 111 may be disposed on the substrate SB. A metal layer BML may be disposed on the buffer layer 111.

A first buffer layer 112 may be disposed on the metal layer BML.

A first semiconductor layer 1300 is disposed on the first buffer layer 112. The first semiconductor layer 1300 may include a polycrystalline semiconductor.

A portion of the first semiconductor layer 1300 may overlap the metal layer BML in a plan view.

A first gate insulating layer 141 may be disposed on the first semiconductor layer 1300.

A first gate conductor including an initialization control line 153, an emission control line 154, and a first capacitor electrode CE1 may be disposed on the first gate insulating layer 141.

A second gate insulating layer 142 may be disposed on the first gate conductor.

A first contact hole CP1a exposing a portion of the first semiconductor layer 1300 is defined in the second gate insulating layer 142 and the first gate insulating layer 141, and a second contact hole CP1b exposing a portion of the metal layer BML may be defined in the second gate insulating layer 142, the first gate insulating layer 141, and the first buffer layer 112. A third contact hole CP1c exposing another portion of the first semiconductor layer 1300 may be defined in the second gate insulating layer 142 and the first gate insulating layer 141.

A second gate conductor including a first initialization voltage line 127 and a second capacitor electrode CE2 may be disposed on the second gate insulating layer 142.

The second capacitor electrode CE2 may connect the metal layer BML and the first semiconductor layer 1300 through the first contact hole CP1a and the second contact hole CP1b.

The first capacitor electrode CE1 and the second capacitor electrode CE2 may constitute a capacitor.

The first interlayer-insulating layer 161 is disposed on the second gate conductor.

The first interlayer-insulating layer 161 may include a first portion 1611 and a second portion 1612 having different heights measured from a surface of the substrate along the first direction Dz, and for example, the first portion 1611 of the first interlayer-insulating layer 161 may be a portion having a relatively low surface height, and the second portion 1612 of the first interlayer-insulating layer 161 may be a portion having a relatively high surface height.

The first portion 1611 and the second portion 1612 of the first interlayer-insulating layer 161 may have a height difference, i.e., a fifth step Hd5.

A fourth contact hole CP2a exposing the second capacitor electrode CE2 is formed in the first interlayer-insulating layer 161, a fifth contact hole CP2b exposing the first capacitor electrode CE1 is formed in the first interlayer-insulating layer 161 and the second gate insulating layer 142, and a sixth contact hole CP2c exposing another portion of the first semiconductor layer 1300 is formed in the first interlayer-insulating layer 161, the second gate insulating layer 142, and the first gate insulating layer 141.

In this case, the fourth contact hole CP2a is formed in the second portion 1612 of the first interlayer-insulating layer 161, and the fifth contact hole CP2b and the sixth contact hole CP2c formed in a relatively large number of insulating layers are formed in the first portion 1611 of the first interlayer-insulating layer 161 having a relatively low height.

Accordingly, it is possible to reduce thicknesses of the insulating layers in which the fifth contact hole CP2b and the sixth contact hole CP2c are formed, and thus, the fifth contact hole CP2b and the sixth contact hole CP2c may be formed without defects without increasing planar areas of the fifth contact hole CP2b and the sixth contact hole CP2c formed in the relatively large number of insulating layers.

A third gate conductor including a first connector 61, a second connector 62, a third connector 63, a fourth connector 64, and a fifth connector 65 is formed on the first interlayer-insulating layer 161.

The second connector 62 is connected to the second capacitor electrode CE2 through the fourth contact hole Cp2a, and the third connector 63 may be connected to the first capacitor electrode CE1 through the fifth contact hole CP2b. The fifth connector 65 may be connected to a portion of the first semiconductor layer 1300 through the sixth contact hole CP2c.

The second interlayer-insulating layer 162 is disposed on the third gate conductor. The second interlayer-insulating layer 162 may include the first portion 1621 and the second portion 1622 having different heights measured from a surface of the substrate along the first direction Dz, and for example, the first portion 1621 of the second interlayer-insulating layer 162 may be a portion having a relatively low surface height, and the second portion 1622 of the second interlayer-insulating layer 162 may be a portion having a relatively high surface height.

The first portion 1621 and the second portion 1622 of the second interlayer-insulating layer 162 may have a height difference, i.e., a sixth step Hd6.

A second semiconductor layer 1400 may be disposed on the second interlayer-insulating layer 162.

A third gate insulating layer 143 may be disposed on the second semiconductor layer 1400. The third gate insulating layer 143 may be formed to cover a portion of the second semiconductor layer 1400.

A fourth gate conductor including a second scan line 152 and an initialization control line 153 may be disposed on the third gate insulating layer 143.

A third interlayer-insulating layer 163 may be disposed on the fourth gate conductor.

The third interlayer-insulating layer 163 may include a first portion 1631 and a second portion 1632 having different heights measured from a surface of the substrate along the first direction Dz, and for example, the first portion 1631 of the third interlayer-insulating layer 163 may be a portion having a relatively low surface height, and the second portion 1632 of the third interlayer-insulating layer 163 may be a portion having a relatively high surface height.

The first portion 1631 and the second portion 1632 of the third interlayer-insulating layer 163 may have a height difference, i.e., a seventh step Hd7.

A seventh contact hole CP4a, an eighth contact hole CP4b, and a ninth contact hole CP4c exposing the second connector 62, the third connector 63, and the fifth connector 65 are formed in the third interlayer-insulating layer 163 and the second interlayer-insulating layer 162.

In addition, a tenth contact hole CP4d, an eleventh contact hole CP4e, and a twelfth contact hole CP4f partially exposing the second semiconductor layer 1400 are formed in the third interlayer-insulating layer 163 and the third gate insulating layer 143. Herein, the seventh contact hole CP4a, the eighth contact hole CP4b, and the ninth contact hole CP4c formed in the third interlayer-insulating layer 163 and the second interlayer-insulating layer 162, which are relatively thick, may be formed in the first portion 1631 of the third interlayer-insulating layer 163 having a relatively low height, thereby reducing depths of the insulating layers in which the seventh contact hole CP4a, the eighth contact hole CP4b, and the ninth contact hole CP4c are formed, and thus the seventh contact hole CP4a, the eighth contact hole CP4b, and the ninth contact hole CP4c may be formed without defects without increasing planar areas of the seventh contact hole CP4a, the eighth contact hole CP4b, and the ninth contact hole CP4c formed in the relatively large number of insulating layers.

A fifth gate conductor including a sixth connector 81, a seventh connector 82, an eighth connector 83, a ninth connector 84, and a tenth connector 85 may be disposed on the third interlayer-insulating layer 163.

The sixth connector 81 may be connected to the second connector 62 through the seventh contact hole Cp4a, the seventh connector 82 may be connected to the third connector 63 through the eighth contact hole Cp4b, and the tenth connector 85 may be connected to the fifth connector 65 through the ninth contact hole CP4c.

In addition, the seventh connector 82 may be connected to a part of the second semiconductor layer 1400 through the twelfth contact hole Cp4f, and the ninth connector 84 may be connected to a portion of the second semiconductor layer 1400 through the tenth contact hole CP4d.

A fourth interlayer-insulating layer 164 may be disposed on the fifth gate conductor. A thirteenth contact hole CP5a exposing the eighth connector 83, a fourteenth contact hole CP5b exposing the sixth connector 81, a fifteenth contact hole CP5c exposing the ninth connector 84, and a sixteenth contact hole CP5d exposing the tenth connector 85 may be formed in the fourth interlayer-insulating layer 164.

A first data conductor including a driving voltage line 172, a reference voltage line 176, an eleventh connector 93, and a twelfth connector 94 may be disposed on the fourth interlayer-insulating layer 164.

A first insulating layer 170 may be disposed on the first data conductor. A seventeenth contact hole CP6a and an eighteenth contact hole CP6b exposing the eleventh connector 93 and the twelfth connector 94 may be formed in the first insulating layer 170.

A second data conductor including a data line 171 and a thirteenth connector 122 may be disposed on the first insulating layer 170.

A second insulating layer 180 is disposed on the second data conductor, and a nineteenth contact hole CP7a exposing the twelfth connector 94 is formed in the second insulating layer 180.

A pixel electrode 191 may be formed on the second insulating layer 180, and may be connected to the thirteenth connector 122 through the nineteenth contact hole CP7a, to be connected to a drain electrode of the first transistor T1.

A pixel opening 365 may be formed in the pixel defining layer 350, and the pixel opening 365 of the pixel defining layer 350 may overlap the pixel electrode 191. An emission layer 370 may be disposed in the pixel opening 365 of the pixel defining layer 350.

A common electrode 270 may be disposed on the emission layer 370 and the pixel defining layer 350.

The pixel electrode 191, the emission layer 370, and the common electrode 270 may constitute a light emitting diode LED. Herein, the pixel electrode 191 may be an anode which is a hole-injection electrode, and the common electrode 270 may be a cathode which is an electron-injection electrode. However, the embodiment according to the invention is not limited thereto, and the pixel electrode 191 may be a cathode and the common electrode 270 may be an anode depending on a driving method of an organic light emitting diode device.

When holes and electrons are injected from the pixel electrode 191 and the common electrode 270 into the emission layer 370, excitons formed by combining the injected holes and electrons are emitted when they fall from an excited state to a ground state.

Although not illustrated, an encapsulation layer (not illustrated) may be disposed on the common electrode 270, and the encapsulation layer may cover not only an upper surface but also a side surface of the pixel to encapsulate a pixel portion. The encapsulation layer may include a plurality of layers, and may be formed as a composite layer including both an inorganic layer and an organic layer.

As such, in accordance with the display device according to an embodiment, surfaces of the first interlayer-insulating layer 161, the second interlayer-insulating layer 162, and the third interlayer-insulating layer 163, which are insulating layers where contact holes are formed, may each have a first portion (1611, 1621, and 1631) and a second portion (1612,1622, and 1632) with steps from each other, and each of the surfaces of the first portions 1611, and 1621, 1631 and the second portion 1612, 1622, and 1632 may be flat. Accordingly, contact holes may be formed without errors in a plurality of insulating layers without increasing planar areas thereof, and disconnection of wires and electrodes formed on the insulating layer may be effectively prevented.

As a size of the pixel PX decreases, a plurality of conductor layers such as a first gate conductor, a second gate conductor, a third gate conductor, a fourth gate conductor, a fifth gate conductor, a first data conductor, and a second data conductor are formed on the substrate SB in order to form a plurality of signal lines included in one pixel PX in a small area. In this case, a plurality of contact holes for connection between the respective conductor layers need to be formed, it is desirable to form the contact holes without defects and without increasing planar areas of the contact holes, and there is a growing need for forming the conductor layers to have a narrow width.

In accordance with the display device according to an embodiment, each of the insulating layers includes a first portion and a second portion having a height difference, and a surface of the first portion and a surface of the second surface are flat. Accordingly, the contact holes may be formed in the first portion of the interlayer-insulating layer having a relatively low height without defects without increasing planar areas of the contact holes, and since the surface of the first portion and the surface of the second portion of each interlayer-insulating layer are flat, even when widths of the conductor layers formed thereon are narrowed, they may be formed on the flat insulating layers, thereby effectively preventing disconnection of the narrow conductor layers.

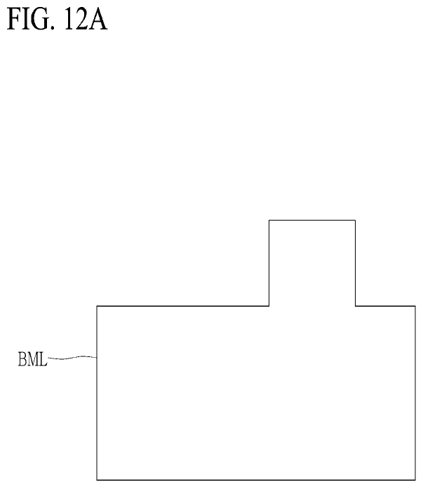

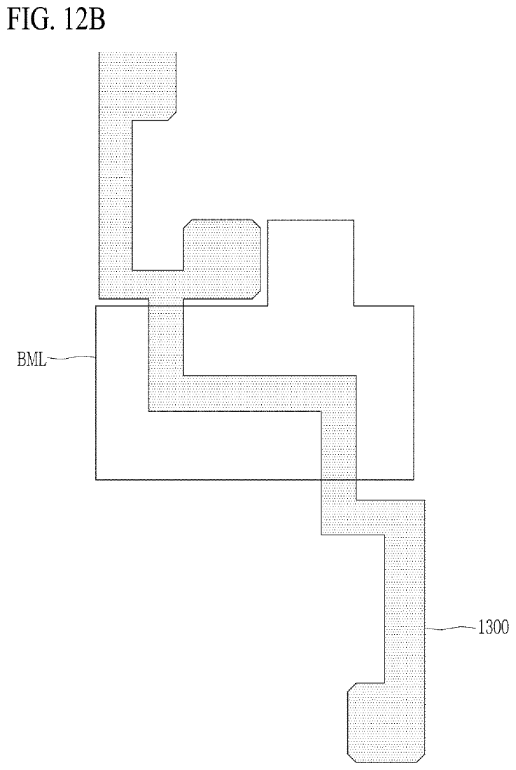

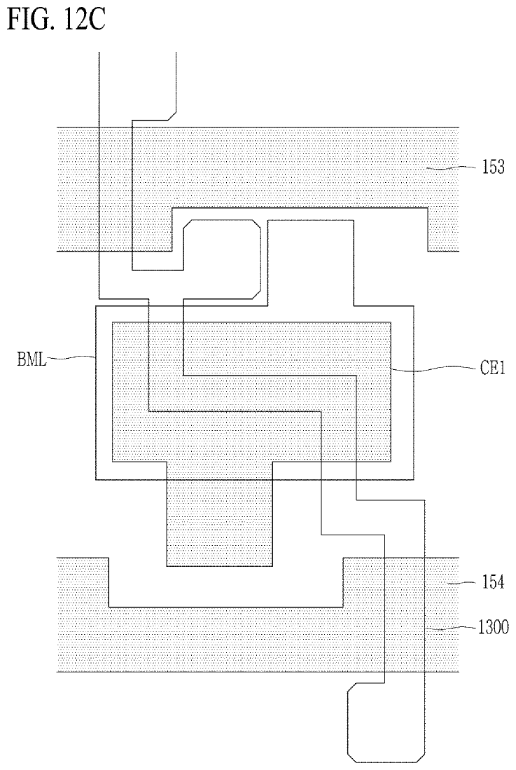

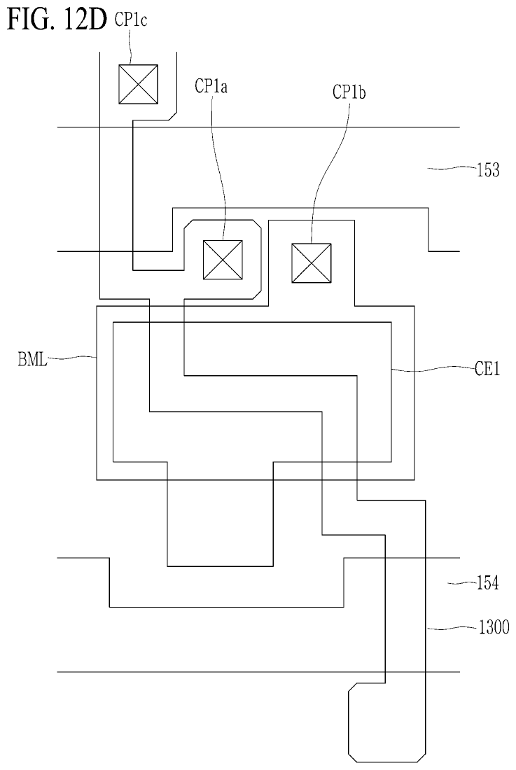

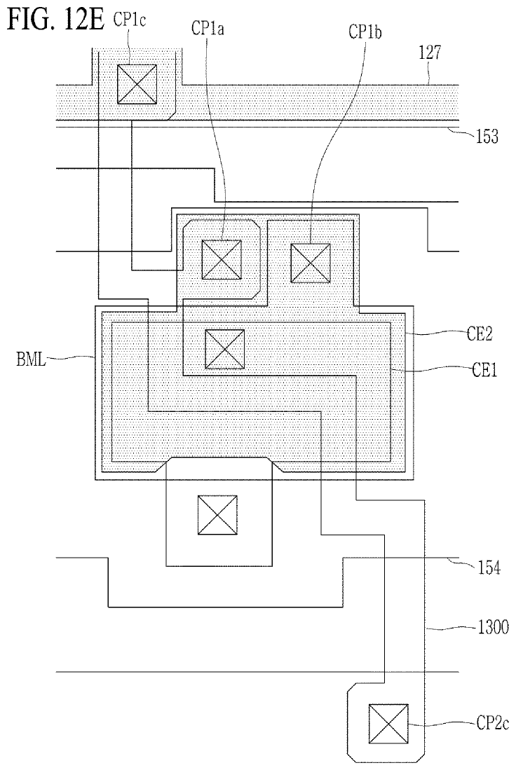

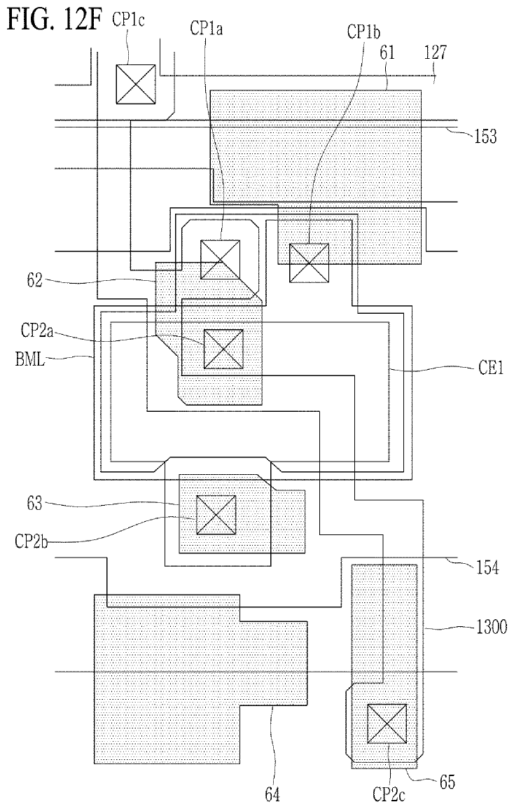

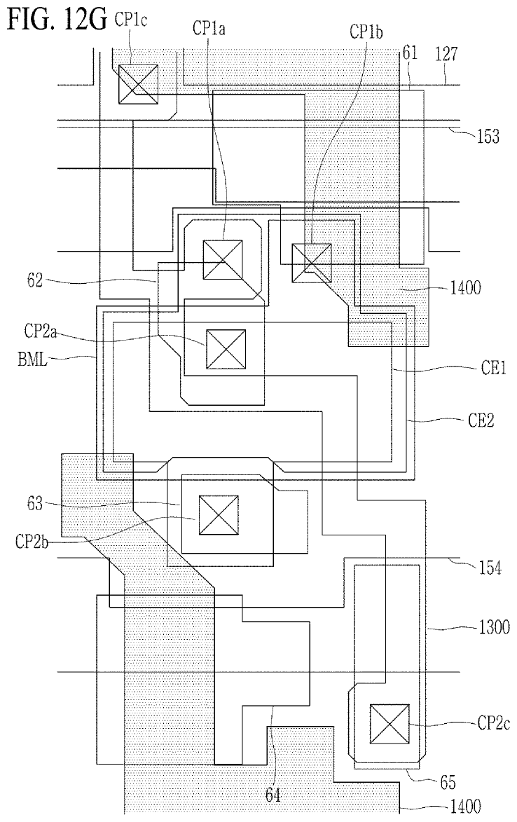

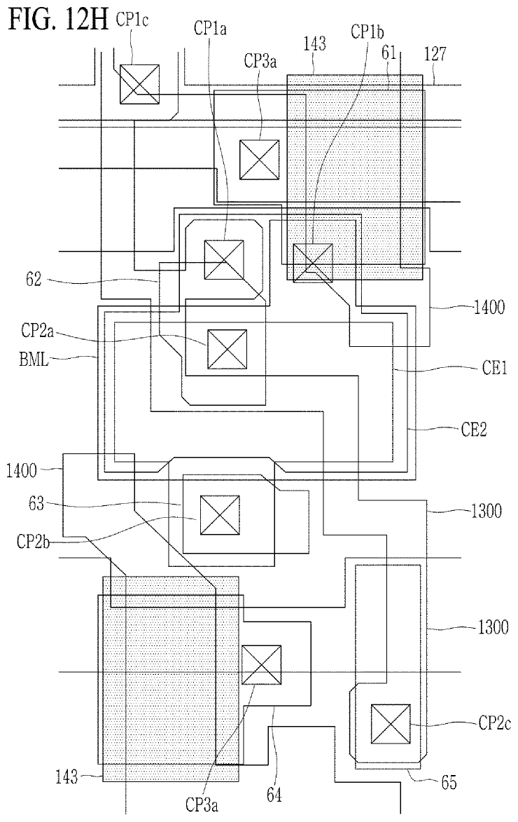

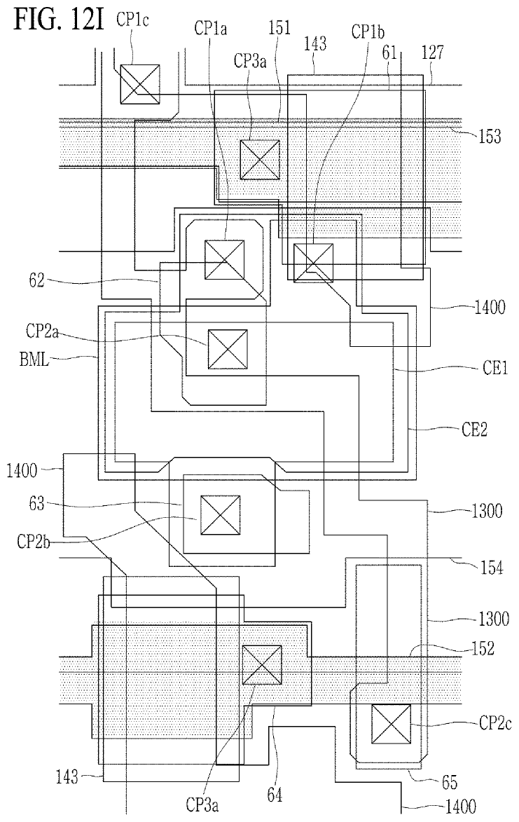

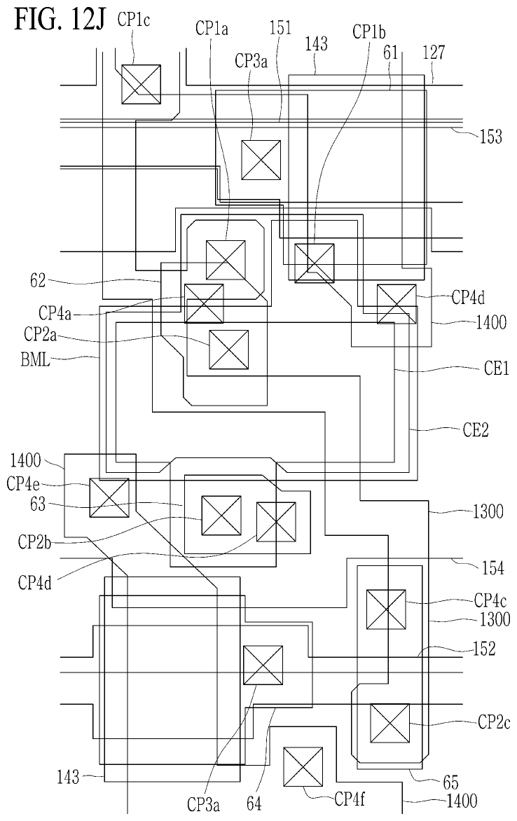

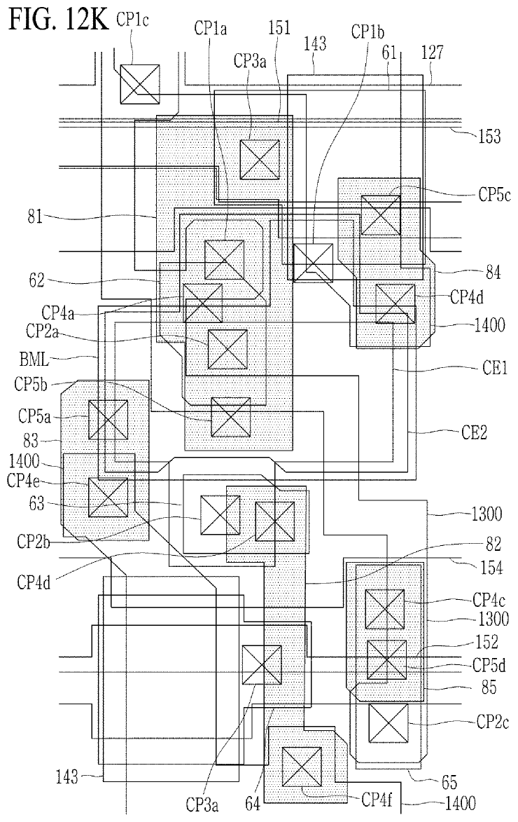

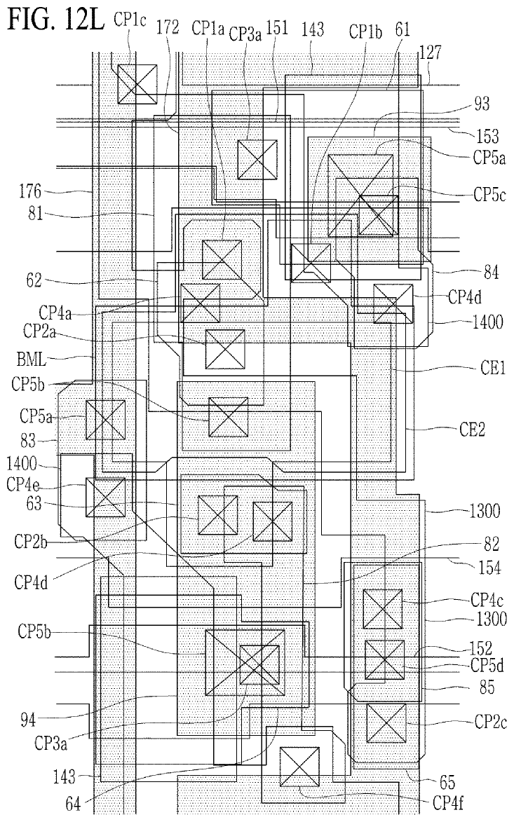

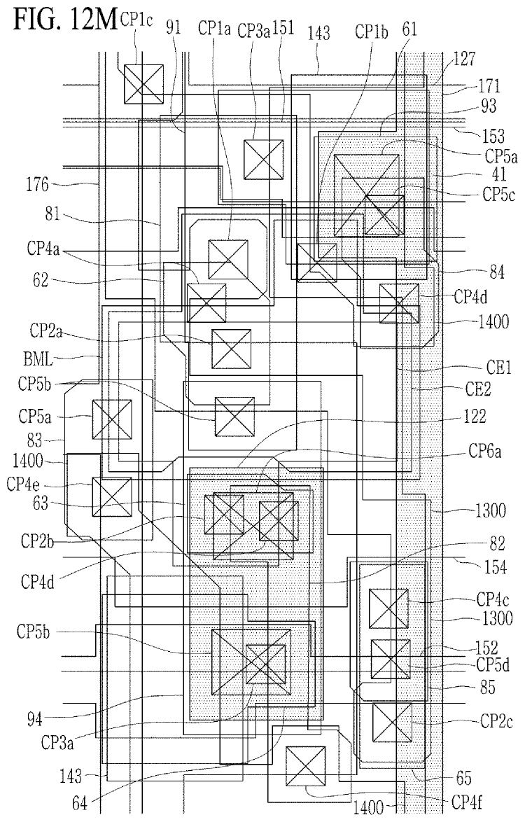

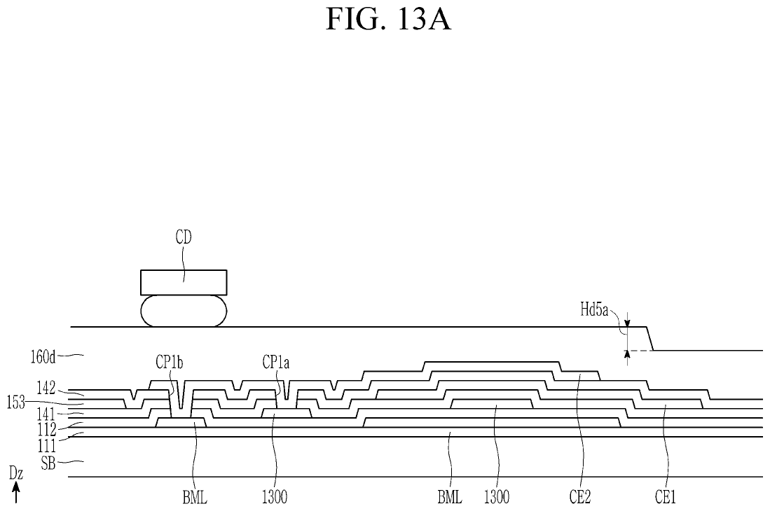

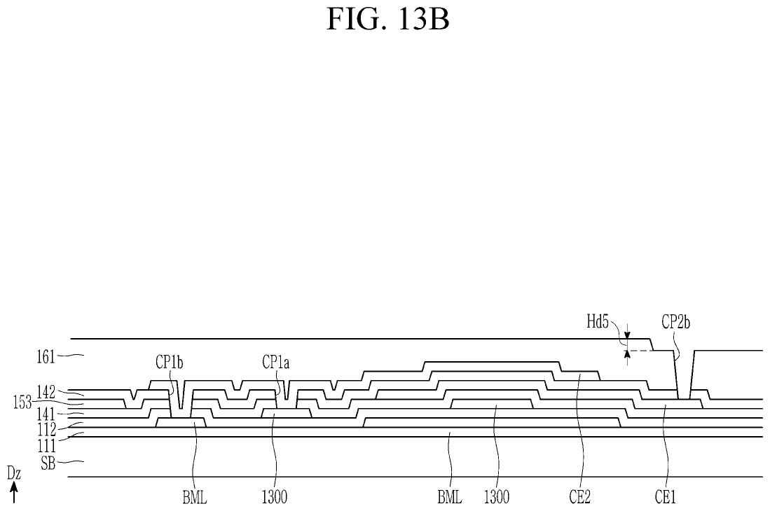

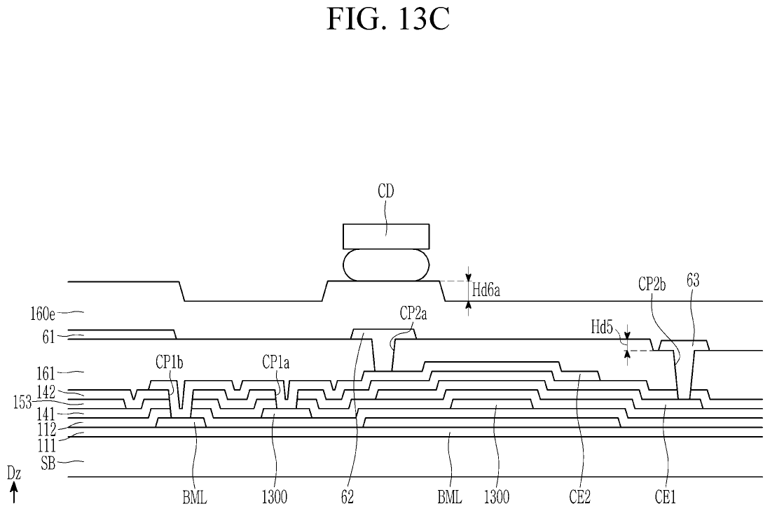

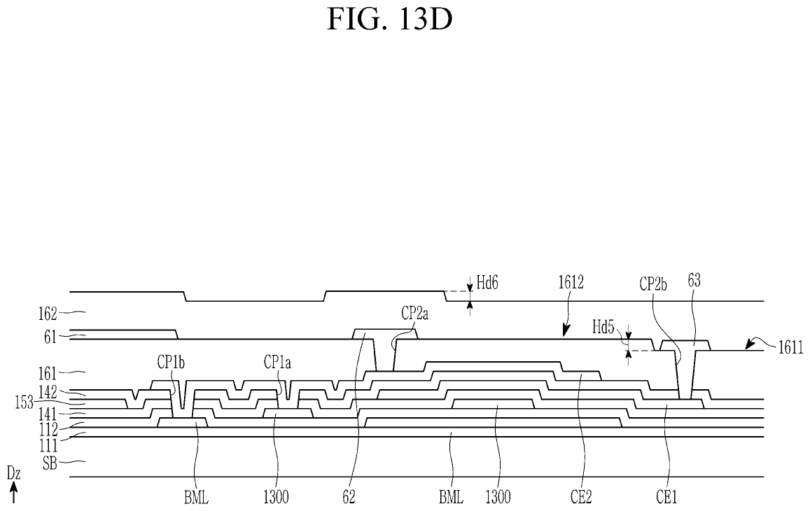

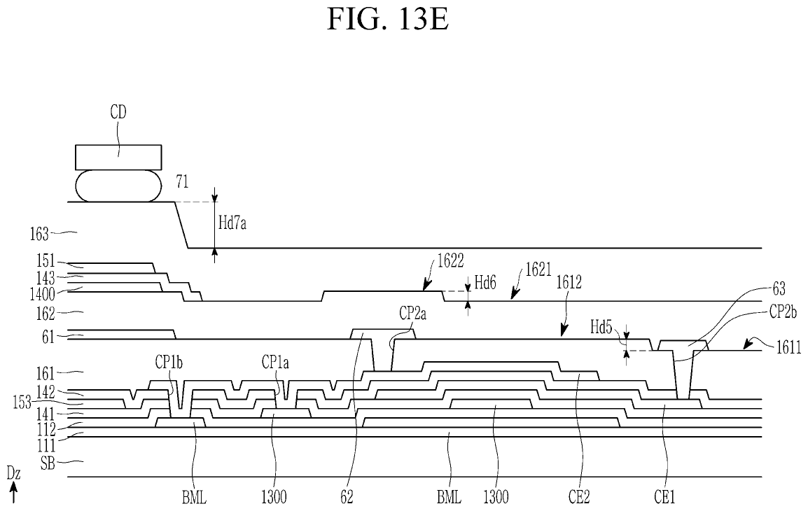

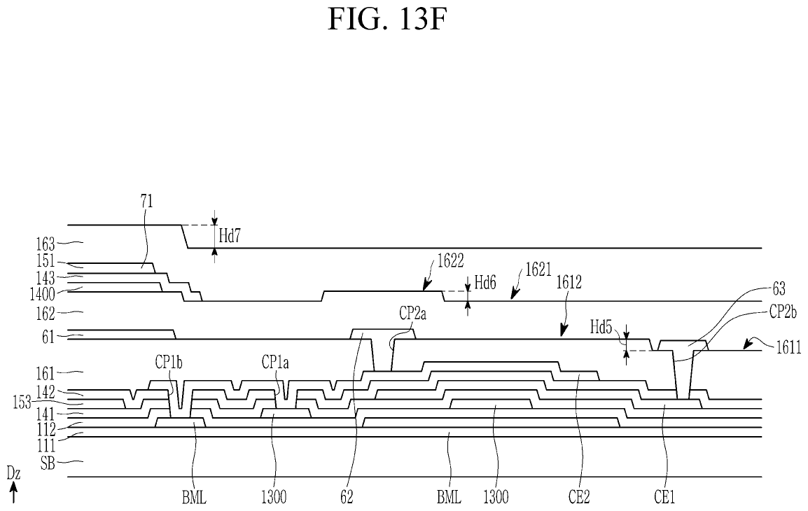

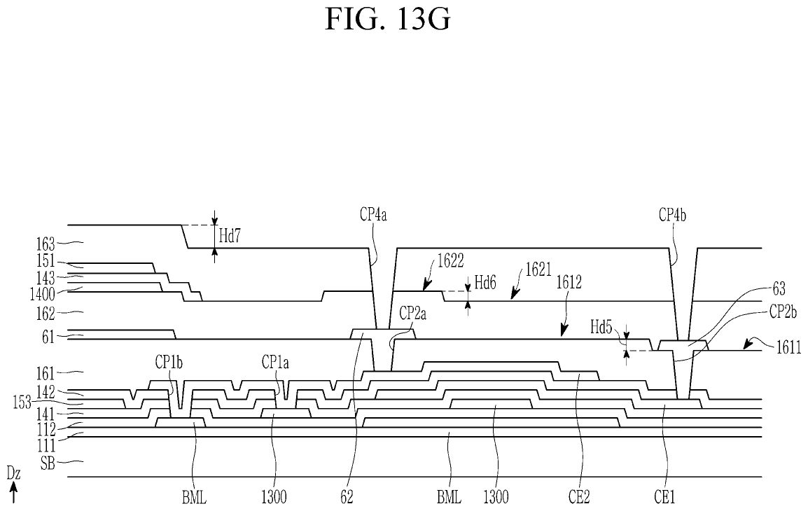

Next, a manufacturing method of a display device according to another embodiment will be described with reference to FIG. 12A to FIG. 12M and FIG. 13A to FIG. 13G along with FIG. 10 and FIG. 11. FIG. 12A to FIG. 12M illustrate top plan views showing a manufacturing method of a display device according to another embodiment, and FIG. 13A to FIG. 13G illustrate cross-sectional views showing a manufacturing method of a display device according to another embodiment.

Referring to FIG. 12A and 13A, a buffer layer 111 is formed on the substrate SB, and a metal layer BML is formed on the buffer layer 111.

Referring to FIG. 12B and FIG. 13A, a first buffer layer 112 is formed on the metal layer BML, and a first semiconductor layer 1300 is formed on the first buffer layer 112. The first semiconductor layer 1300 may be formed to include a polycrystalline semiconductor.

Referring to FIG. 12C and FIG. 13A, a first gate insulating layer 141 is formed on the first semiconductor layer 1300, and a first gate conductor including an initialization control line 153, an emission control line 154, and a first capacitor electrode CE1 is formed on the first gate insulating layer 141.

Referring to 12D and 13A, a second gate insulating layer 142 is deposited on the first gate conductor, a first contact hole CP1a exposing a portion of the first semiconductor layer 1300 is formed in the second gate insulating layer 142 and the first gate insulating layer 141, a second contact hole CP1b exposing a portion of the metal layer BML is formed in the second gate insulating layer 142, the first gate insulating layer 141, and the first buffer layer 112, and a third contact hole CP1c exposing another portion of the first semiconductor layer 1300 is formed in the second gate insulating layer 142 and the first gate insulating layer 141.

Referring to FIG. 12E and FIG. 13A, a second gate conductor including a first initialization voltage line 127 and a second capacitor electrode CE2 is formed on the second gate insulating layer 142, an insulating layer 160d having a different height measured from a surface of the substrate along the first direction Dz depending on a position thereof and having a step Hd5a that is greater than a fifth step Hd5 of the first interlayer-insulating layer 161 is deposited, and a surface of the insulating layer 160d is polished by using a planarization device CD.

Through this polishing process, as illustrated in FIG. 12F and FIG. 13B, the first portion 1611 and the second portion 1612 having different heights measured from the surface of the substrate surface along the first direction Dz, the first interlayer-insulating layer 161 is formed such that the first portion 1611 and the second portion 1612 of the first interlayer-insulating layer 161 have a height difference, i.e., a fifth step Hd5, the fourth contact hole CP2a exposing the second capacitor electrode CE2 is formed in the first interlayer-insulating layer 161, the fifth contact hole CP2b exposing the first capacitor electrode CE1 is formed in the first interlayer-insulating layer 161 and the second gate insulating layer 142, and the sixth contact hole CP2c exposing another portion of the first semiconductor layer 1300 is formed in the first interlayer-insulating layer 161, the second gate insulating layer 142, and the first gate insulating layer 141.

In this case, the fourth contact hole CP2a is formed in the second portion 1612 of the first interlayer-insulating layer 161, and the fifth contact hole CP2b and the sixth contact hole CP2c formed in a relatively large number of insulating layers are formed in the first portion 1611 of the first interlayer-insulating layer 161 having a relatively low height.

Accordingly, it is possible to reduce thicknesses of the insulating layers in which the fifth contact hole CP2b and the sixth contact hole CP2c are formed, and thus, the fifth contact hole CP2b and the sixth contact hole CP2c may be formed without defects without increasing planar areas of the fifth contact hole CP2b and the sixth contact hole CP2c formed in the relatively large number of insulating layers.

Referring to FIG. 12G and FIG. 13C, a third gate conductor including a first connector 61, a second connector 62, a third connector 63, a fourth connector 64, and a fifth connector 65 is formed on the first interlayer-insulating layer 161, an insulating layer 160e having a different height measured from the surface of the substrate along the first direction Dz depending on a position thereof and having a step Hd6a that is greater than a sixth step Hd6 of the second interlayer-insulating layer 162 is deposited on the third gate conductor, a surface of the insulating layer 160e is polished by using the planarization device CD, the first portion 1621 and the second portion 1622 having different heights measured from the surface of the substrate along the first direction Dz are included as illustrated in FIG. 13D, and the second interlayer-insulating layer 162 is formed such that the first portion 1621 and the second portion 1622 of the second interlayer-insulating layer 162 have a height difference, i.e., a sixth step Hd6 in the first direction Dz.

As illustrated in FIG. 12H and FIG. 13E, a second semiconductor layer 1400 is formed on the second interlayer-insulating layer 162, and as illustrated in FIG. 121 and FIG. 13E, a third gate insulating layer 143 is formed on the second semiconductor layer 1400 to cover a portion of the second semiconductor layer 1400.

As illustrated in FIG. 13E, a fourth gate conductor including a second scan line 152 and an initialization control line 153 is formed on the third gate insulating layer 143, an insulating layer 160f having a different height measured from the surface of the substrate along the first direction Dz depending on a position thereof and having a step Hd7a that is greater than a seventh step Hd7 of the third interlayer-insulating film 163 is deposited on the fourth gate conductor, a surface of the insulating layer 160f is polished by using the planarization device CD, the first portion 1631 and the second portion 1632 having different heights measured from the surface of the substrate surface along the first direction Dz are included as illustrated in FIG. 13F, and the third interlayer-insulating layer 163 is formed such that the first portion 1631 and the second portion 1632 have a height difference, i.e., a seventh step Hd7.

As illustrated in FIG. 12J and FIG. 13G, a seventh contact hole CP4a, an eighth contact hole CP4b, and a ninth contact hole CP4c are formed to expose the second connector 62, the third connector 63, and the fifth connector 65 in the third interlayer-insulating layer 163 and the second interlayer-insulating layer 162, and a tenth contact hole CP4d, an eleventh contact hole CP4e, and a twelfth contact hole CP4f exposing a part of the second semiconductor layer 1400 are formed in the third interlayer-insulating layer 163 and the third gate insulating layer 143. In this case, the seventh contact hole CP4a, the eighth contact hole CP4b, and the ninth contact hole CP4c formed in the third interlayer-insulating layer 163 and the second interlayer-insulating layer 162, which are relatively thick, may be formed in the first portion 1631 of the third interlayer-insulating layer 163 having a relatively low height, thereby reducing depths of the insulating layers in which the seventh contact hole CP4a, the eighth contact hole CP4b, and the ninth contact hole CP4c are formed, and thus the seventh contact hole CP4a, the eighth contact hole CP4b, and the ninth contact hole CP4c may be formed without defects without increasing planar areas of the seventh contact hole CP4a, the eighth contact hole CP4b, and the ninth contact hole CP4c formed in the relatively large number of insulating layers.

Referring to FIG. 10 together with FIG. 12K, a fifth gate conductor including a sixth connector 81, a seventh connector 82, an eighth connector 83, a ninth connector 84, and a tenth connector 85 are formed on the third interlayer-insulating layer 163, a fourth interlayer-insulating layer 164 is formed on the fifth gate conductor, and a thirteenth contact hole CP5a exposing the eighth connector 83, a fourteenth contact hole CP5b exposing the sixth connector 81, a fifteenth contact hole CP5c exposing the ninth connector 84, and a sixteenth contact hole CP5d exposing the tenth connector 85 is formed in the fourth interlayer-insulating layer 164.

Referring to FIG. 10 together with FIG. 12L, a first data conductor including a driving voltage line 172, a reference voltage line 176, an eleventh connector 93, and a twelfth connector 94 is formed on the fourth interlayer-insulating layer 164, a first insulating layer 170 is deposited on the first data conductor, and the seventeenth contact hole CP6a and the eighteenth contact hole CP6b exposing the eleventh connector 93 and the twelfth connector 94 are formed in the first insulating layer 170.

Referring to FIG. 10 together with FIG. 12M, a second data conductor including a data line 171 and a thirteenth connector 122 is formed on the first insulating layer 170.

Next, a second insulating layer 180 is formed on the second data conductor, a pixel electrode 191 is formed on the second insulating layer 180, a pixel defining layer 350 is formed on the pixel electrode 191, a light emission layer 370 is formed in the pixel opening 365 of the pixel defining layer 350, and a common electrode 270 is formed on the emission layer 370 and the pixel defining layer 350 to form the display device illustrated in FIG. 9 and FIG. 11.

As such, in accordance with the manufacturing method of the display device according to the present embodiment, surfaces of the first interlayer-insulating layer 161, the second interlayer-insulating layer 162, and the third interlayer-insulating layer 163, which are insulating layers where contact holes are formed, may each have a first portion (1611, 1621, and 1631) and a second portion (1612, 1622, and 1632) with steps from each other, and each of the upper surfaces of the first portions 1611, and 1621, 1631 and the second portions 1612, 1622, and 1632 may be flat. Accordingly, contact holes may be formed without errors in a plurality of insulating layers without increasing planar areas thereof, and disconnection of wires and electrodes disposed on the insulating layer may be effectively prevented.

In accordance with the manufacturing method of the display device according to an embodiment, each of the insulating layers includes a first portion and a second portion having a height difference, and a surface of the first portion and a surface of the second surface are flat. Accordingly, the contact holes may be formed in the first portion of the interlayer-insulating layer having a relatively low height without defects without increasing planar areas of the contact holes, and since the surface of the first portion and the surface of the second portion of each interlayer-insulating layer are flat, even when widths of the conductor layers formed thereon are narrowed, they may be disposed on the flat insulating layers, thereby effectively preventing disconnection of the narrow conductor layers.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

111, 112: buffer layer

127, 128: initialization voltage line

130, 135, 1300, 1400: semiconductor

141, 142, 143: gate insulating layer

151, 152: scan line

153, 154, 155: control line

160, 180: insulating layer

161, 162, 163, 164: interlayer-insulating layer

171: data line

172: driving voltage line

176: reference voltage line

191: pixel electrode

270: common electrode

370: emission layer

741: common voltage line

What is claimed is:

1. A display device comprising:
a substrate;
a first signal line and a second signal line disposed on the substrate; and
an interlayer-insulating layer disposed between the first signal line and the second signal line,
wherein the interlayer-insulating layer includes a first portion and a second portion having different heights measured from a major surface of the substrate along a first direction that is perpendicular to the major surface of the substrate,
an upper surface of the first portion of the interlayer-insulating layer is flat, an upper surface of the second portion of the interlayer-insulating layer is flat,
a height of the first portion is lower than a height of the second portion,
the interlayer-insulating layer defines a contact hole therein, and
the contact hole is disposed in the first portion of the interlayer-insulating layer.

2. The display device of claim 1, wherein
the first portion of the interlayer-insulating layer overlaps the first signal line and the second signal line in a plan view, and
the contact hole of the interlayer-insulating layer exposes a portion of the first signal line.

3. The display device of claim 2, wherein
the first portion and the second portion are polished.

4. The display device of claim 3, wherein
the interlayer-insulating layer includes a first layer and a second layer disposed on the first layer, and
a height of a portion of the second layer disposed at the second portion of the interlayer-insulating layer is the same as a height of a portion of the first layer disposed at the second portion of the interlayer-insulating layer.

5. The display device of claim 4, wherein
the first layer includes a silicon nitride, and the second layer includes a silicon oxide.

6. The display device of claim 5, further comprising
a first capacitor electrode and a second capacitor electrode overlapping each other in the plan view with the interlayer-insulating layer therebetween, and
the first capacitor electrode and the second capacitor electrode overlap the first portion of the interlayer-insulating layer in the plan view.

7. The display device of claim 6, further comprising:
a first interlayer-insulating layer disposed on the first signal line and the second signal line; and
a third signal line disposed on the first interlayer-insulating layer,
wherein the first interlayer-insulating layer includes a third portion and a fourth portion having different heights measured from the surface of the substrate along the first direction,
an upper surface of the third portion of the first interlayer-insulating layer is flat, and an upper surface of the fourth portion of the first interlayer-insulating layer is flat.

8. The display device of claim 7, further comprising
a second interlayer-insulating layer disposed on the third signal line,
wherein the second interlayer-insulating layer includes a fifth portion and a sixth portion having different heights measured from the surface of the substrate along the first direction,
an upper surface of the fifth portion of the second interlayer-insulating layer is flat, and an upper surface of the sixth portion of the second interlayer-insulating layer is flat.

9. The display device of claim 1, further comprising
a first capacitor electrode and a second capacitor electrode overlapping each other in a plan view with the interlayer-insulating layer therebetween, and
the first capacitor electrode and the second capacitor electrode overlap the first portion of the interlayer-insulating layer in the plan view.

10. The display device of claim 9, further comprising:
a first interlayer-insulating layer disposed on the first signal line and the second signal line; and
a third signal line disposed on the first interlayer-insulating layer,
wherein the first interlayer-insulating layer includes a third portion and a fourth portion having different heights measured from the surface of the substrate along the first direction,
an upper surface of the third portion of the first interlayer-insulating layer is flat, and an upper surface of the fourth portion of the first interlayer-insulating layer is flat.

11. The display device of claim 10, further comprising
a second interlayer-insulating layer disposed on the third signal line,
wherein the second interlayer-insulating layer includes a fifth portion and a sixth portion having different heights measured from the surface of the substrate along the first direction,
an upper surface of the fifth portion of the second interlayer-insulating layer is flat, and an upper surface of the sixth portion of the second interlayer-insulating layer is flat.

12. A manufacturing method of a display device, comprising:
forming a first signal line on a substrate;
stacking an insulating layer on the first signal line, the insulating layer including a first portion and a second portion having different heights measured from a surface of the substrate along a first direction that is perpendicular to the surface of the substrate;
forming an interlayer-insulating layer including a third portion and a fourth portion having different heights measured from the surface of the substrate along the first direction by polishing a surface of the insulating layer;
forming a contact hole in the interlayer-insulating layer; and
forming a second signal line on the interlayer-insulating layer,
wherein an upper surface of the third portion of the interlayer-insulating layer is formed to be flat, an upper surface of the fourth portion of the interlayer-insulating layer is formed to be flat,
the interlayer-insulating layer is formed such that a height of the third portion is lower than a height of the fourth portion, and
the contact hole of the interlayer-insulating layer is disposed in the third portion of the interlayer-insulating layer.

13. The manufacturing method of claim 12, wherein
a first surface step difference between the first portion and the second portion of the insulating layer is greater than a second surface step difference between the third portion and the fourth portion of the interlayer-insulating layer.

14. The manufacturing method of claim 13, wherein
the forming of the contact hole includes forming the contact hole of the interlayer-insulating layer to overlap the first signal line.

15. The manufacturing method of claim 12, wherein
the forming of the interlayer-insulating layer includes polishing the first portion and the second portion using a planarization device.

16. The manufacturing method of claim 12, wherein
the stacking of the insulating layer includes stacking a first layer and stacking a second layer on the first layer, and
the polishing of the surface of the insulating layer includes polishing the second layer by using the first layer as a stopper.

17. The manufacturing method of claim 16, wherein
the first layer includes a silicon nitride and the second layer includes a silicon oxide.

18. The manufacturing method of claim 12, further comprising:
forming a first capacitor electrode and a second capacitor electrode overlapping each other with the interlayer-insulating layer therebetween in a plan view,
wherein the first capacitor electrode and the second capacitor electrode are formed to overlap the third portion of the interlayer-insulating layer in the plan view.

19. The manufacturing method of claim 12, further comprising:
forming a first interlayer-insulating layer disposed on the first signal line and the second signal line;
forming a third signal line on the first interlayer-insulating layer;
wherein the forming of the first interlayer-insulating layer includes:
stacking a first insulating layer on the first signal line and the second signal line, the first insulating layer including a fifth portion and a sixth portion having different heights measured from the surface of the substrate along the first direction; and
forming the first interlayer-insulating layer including a seventh portion and an eighth portion having different heights measured from the surface of the substrate along the first direction by polishing the first insulating layer, and
wherein an upper surface of the seventh portion of the first interlayer-insulating layer is formed to be flat, and an upper surface of the eighth portion of the first interlayer-insulating layer is formed to be flat.

20. The manufacturing method of claim 19, further comprising
forming a second interlayer-insulating layer on the third signal line,
wherein the forming of the second interlayer-insulating layer includes:
stacking a second insulating layer on the third signal line, the second insulating layer including a ninth portion and a tenth portion having different heights measured from the surface of the substrate along the first direction; and
forming the second interlayer-insulating layer including an eleventh portion and a twelfth portion having different heights measured from the surface of the substrate along the first direction by polishing the second insulating layer, and
wherein an upper surface of the eleventh portion of the second interlayer-insulating layer is formed to be flat, and an upper surface of the twelfth portion of the second interlayer-insulating layer is formed to be flat.
